(19) United States
(12) Patent Application Publication
(10) Pub. No.: US 2023/0174853 A1
(43) Pub. Date: Jun. 8, 2023

(54) QUANTUM DOT COMPOSITION, DISPLAY APPARATUS AND MANUFACTURING METHOD OF THE SAME

(71) Applicant: Samsung Display Co., Ltd., Yongin-si (KR)

(72) Inventors: SANGHEE YU, Hwaseong-si (KR); GYUBONG KIM, Suwon-si (KR); HOI-LIM KIM, Seoul (KR)

(73) Assignee: Samsung Display Co., Ltd., Yongin-si (KR)

(21) Appl. No.: 18/076,597

(22) Filed: Dec. 7, 2022

(30) Foreign Application Priority Data
Dec. 7, 2021 (KR) 10-2021-0174213
Oct. 4, 2022 (KR) 10-2022-0126543

(51) Int. Cl. C09K 11/06; H01L 33/50; B82Y 20/00

(52) U.S. Cl. CPC C09K 11/06; H01L 33/504; B82Y 20/00; H01L 2933/0041

(57) ABSTRACT

A quantum dot composition according to an embodiment of the disclosure includes a quantum dot, a first compound including a first functional group, and a solvent, and the first functional group includes at least one among an acetal group and a ketal group.

### CROSS REFERENCE TO RELATED APPLICATION(S)

This application claims priority to and benefits of Korean Patent Application No. 10-2021-0174213 filed on Dec. 7, 2021 and Korean Patent Application No. 10-2022-0126543 filed on Oct. 4, 2022 in the Korean Intellectual Property Office (KIPO) under 35 U.S.C. § 119, the entire contents of which are incorporated herein by reference.

### BACKGROUND

### 1. Technical Field

The disclosure herein relates to a quantum dot composition, a display apparatus, and a manufacturing method of the same, and to a display apparatus having improved emission efficiency and reliability and a manufacturing method of the same.

### 2. Description of the Related Art

A display panel includes a transmission-type display panel which selectively transmits source light produced from a light source and an emissive-type display panel which produces source light at the display panel itself. The display panel may include different types of color controlling layers according to pixels for producing color images. The color controlling layer may transmit a partial wavelength region of the source light, or may change the color of the source light. Some color controlling layers may not change the color of the source light but may change the characteristics of light.

### SUMMARY

The disclosure provides a quantum dot composition which may be used in the light controlling layer of a display apparatus and show improved emission efficiency properties and reliability.

The disclosure also provides a display apparatus having improved emission efficiency and reliability.

The disclosure also provides a manufacturing method of the display apparatus having improved emission efficiency and reliability.

An embodiment of the disclosure provides a quantum dot composition including a quantum dot, a compound including a first functional group, and a solvent, wherein the first functional group may include at least one among an acetal group and a ketal group.

In an embodiment, an amount of the compound may be about 30 wt % or less based on about 100 wt % of a total amount of the quantum dot composition.

In an embodiment, the compound may be represented by Formula 1 below.

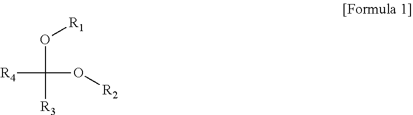

In Formula 1, R₁ and R₂ may be each independently a substituted or unsubstituted alkyl group of 1 to 20 carbon atoms, or R₁ and R₂ may be combined with each other to form a ring, and R₃ and R₄ may be each independently a hydrogen atom, a deuterium atom, a halogen atom, a substituted or unsubstituted alkyl group of 1 to 20 carbon atoms, a substituted or unsubstituted alkenyl group of 2 to 20 carbon atoms, a substituted or unsubstituted alkynyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms.

In an embodiment, the compound may be represented by any one among Formula 1-1 to Formula 1-3 below.

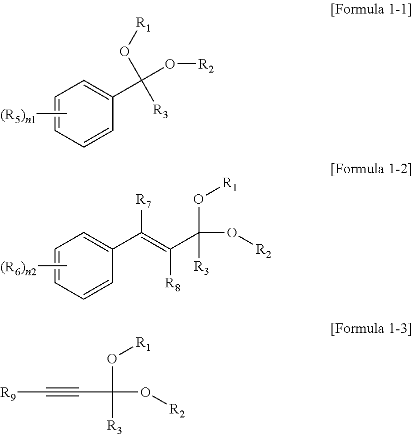

In Formula 1-1 to Formula 1-3, R₅ and R₆ may be each independently a hydrogen atom, a deuterium atom, a halogen atom, a substituted or unsubstituted carboxyl group, a substituted or unsubstituted thio group, a substituted or unsubstituted amine group, a substituted or unsubstituted phosphine group, a substituted or unsubstituted hydroxyl group, a substituted or unsubstituted oxy group, a substituted or unsubstituted nitro group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring, R₇ to R₉ may be each independently a hydrogen atom, a deuterium atom, a halogen atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, and n1 and n2 may be each independently an integer of 0 to 5.

In Formula 1-1 to Formula 1-3, the same explanation defined in Formula 1 may be applied for R₁ to R₃.

In an embodiment, the compound may further include a second functional group which is bonded to a surface of the quantum dot and is different from the first functional group.

In an embodiment, the second functional group may include at least one among a carboxyl group, a thio group, an amine group, a phosphine group, and a hydroxyl group.

In an embodiment, the compound may be represented by any one among Formula 2-1 to Formula 2-5 below.

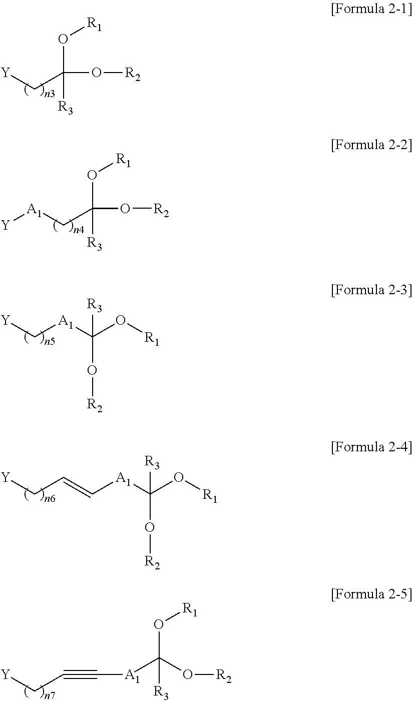

In Formula 2-1 to Formula 2-5, R₁ and R₂ may be each independently a substituted or unsubstituted alkyl group of 1 to 20 carbon atoms, or R₁ and R₂ may be combined with each other to form a ring, R₃ may be a hydrogen atom, a deuterium atom, a halogen atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, Y may be a substituted or unsubstituted carboxyl group, a substituted or unsubstituted thio group, a substituted or unsubstituted amine group, a substituted or unsubstituted phosphine group, or a substituted or unsubstituted hydroxyl group, A₁ may be a substituted or unsubstituted arylene group of 6 to 30 ring-forming carbon atoms, or a substituted or unsubstituted heteroarylene group of 2 to 30 ring-forming carbon atoms, and n3 to n7 may be each independently an integer of 0 to 20.

In an embodiment, the compound may further include a third functional group which is different from the first functional group, and the third functional group may include a (meth)acrylate group.

In an embodiment, a boiling point of the compound may be about 180° C. or higher.

In an embodiment, the quantum dot may include a core and a shell wrapping the core.

According to an embodiment of the disclosure, there may be provided a display apparatus including a light emitting device outputting source light, and a light controlling layer disposed on the light emitting device and including multiple light controlling parts, wherein at least one among the multiple light controlling parts may include a quantum dot and an additive, the additive may include a first functional group or a group formed by a hydrolysis of the first functional group, and the first functional group may include at least one among an acetal group and a ketal group.

In an embodiment, the additive may be represented by Formula 1 or Formula 1A below.

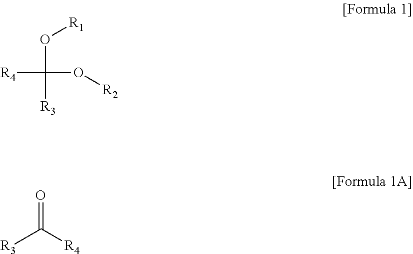

In Formula 1 and Formula 1A, R₁ and R₂ may be each independently a substituted or unsubstituted alkyl group of 1 to 20 carbon atoms, or R₁ and R₂ may be combined with each other to form a ring, and R₃ and R₄ may be each independently a hydrogen atom, a deuterium atom, a halogen atom, a substituted or unsubstituted alkyl group of 1 to 20 carbon atoms, a substituted or unsubstituted alkenyl group of 2 to 20 carbon atoms, a substituted or unsubstituted alkynyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms.

In an embodiment, the additive may be represented by any one among Formula 1-1 to Formula 1-6 below.

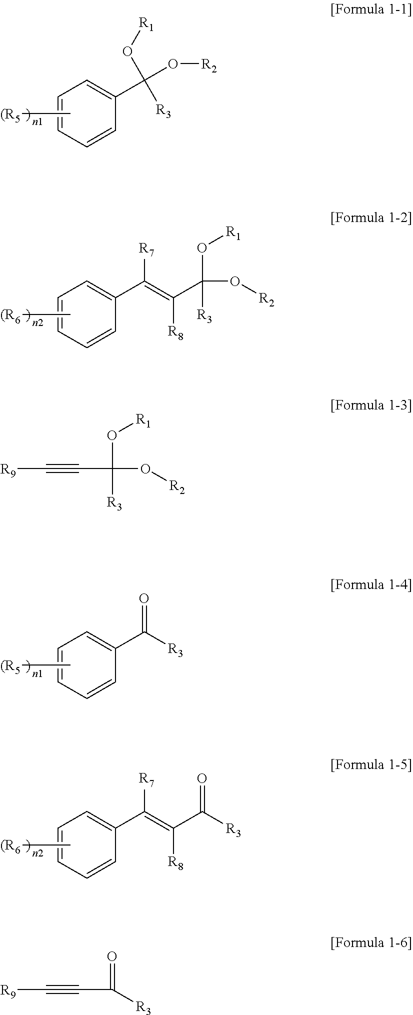

In Formula 1-1 to Formula 1-6, R₁ and R₂ may be each independently a substituted or unsubstituted alkyl group of 1 to 20 carbon atoms, or R₁ and R₂ may be combined with each other to form a ring, R₃ and R₄ may be each independently a hydrogen atom, a deuterium atom, a halogen atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, R₅ and R₆ may be each independently a hydrogen atom, a deuterium atom, a halogen atom, a substituted or unsubstituted carboxyl group, a substituted or unsubstituted thio group, a substituted or unsubstituted amine group, a substituted or unsubstituted phosphine group, a substituted or unsubstituted hydroxyl group, a substituted or unsubstituted oxy group, a substituted or unsubstituted nitro group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring, R₇ to R₉ may be each independently a hydrogen atom, a deuterium atom, a halogen atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, and n1 and n2 may be each independently an integer of 0 to 5.

In an embodiment, the additive may further include a second functional group which is bonded to a surface of the quantum dot and is different from the first functional group, and the second functional group may include at least one among a carboxyl group, a thio group, an amine group, a phosphine group, and a hydroxyl group.

In an embodiment, the additive may be represented by any one among Formula 2-1 to Formula 2-10 below.

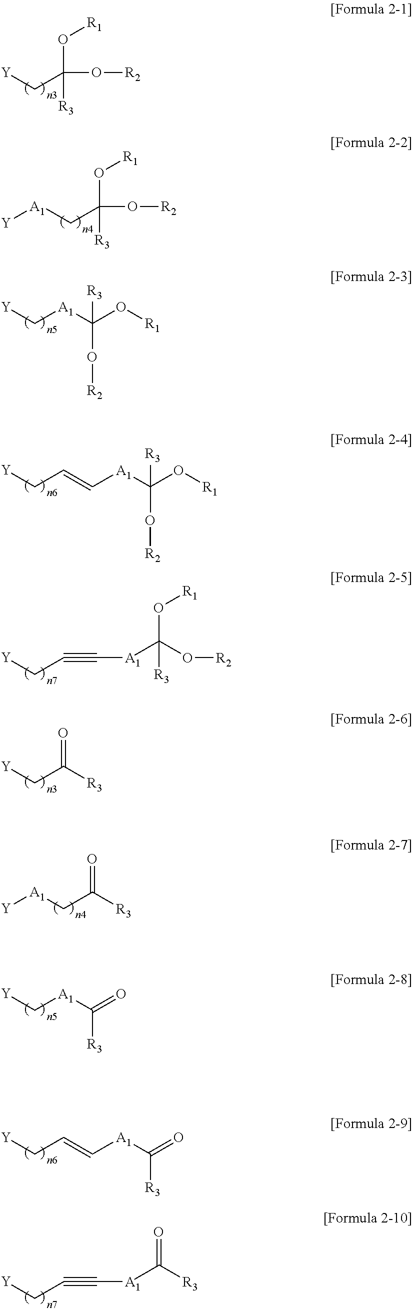

In Formula 2-1 to Formula 2-10, R₁ and R₂ may be each independently a substituted or unsubstituted alkyl group of 1 to 20 carbon atoms, or R₁ and R₂ may be combined with each other to form a ring, R₃ may be a hydrogen atom, a deuterium atom, a halogen atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, Y may be a substituted or unsubstituted carboxyl group, a substituted or unsubstituted thio group, a substituted or unsubstituted amine group, a substituted or unsubstituted phosphine group, or a substituted or unsubstituted hydroxyl group, A₁ may be a substituted or unsubstituted arylene group of 6 to 30 ring-forming carbon atoms, or a substituted or unsubstituted heteroarylene group of 2 to 30 ring-forming carbon atoms, and n3 to n7 may be each independently an integer of 0 to 20.

In an embodiment, the additive may further include a third functional group which is different from the first functional group, and the third functional group may include a (meth)acrylate group.

In an embodiment, the source light may be light of a first wavelength, and the light controlling layer may include a first light controlling part converting the source light into light of a second wavelength which is different from the first wavelength, a second light controlling part converting the source light into light of a third wavelength which is different from the first wavelength and the second wavelength, and a third light controlling part transmitting the source light.

According to an embodiment of the disclosure, there may be provided a manufacturing method of a display apparatus, including preparing a display panel, and forming a light controlling layer including multiple light controlling parts on the display panel, wherein the forming of the light controlling layer comprising the multiple light controlling parts on the display panel may include forming at least one light controlling part among the multiple light controlling parts on the display panel, the forming of at least one light controlling part among the multiple light controlling parts on the display panel, may include providing a quantum dot composition including a quantum dot, and a compound including a first functional group to form a preliminary light controlling part, and drying or heating the preliminary light controlling part at a temperature, the first functional group may include at least one among an acetal group and a ketal group.

In an embodiment, an amount of the compound may be about 30 wt % or less based on about 100 wt % of a total amount of the quantum dot composition.

In an embodiment, the temperature may be lower than a boiling point of the first compound.

However, embodiments of the disclosure are not limited to those set forth herein. The above and other embodiments will become more apparent to one of ordinary skill in the art to which the disclosure pertains by referencing the detailed description of the disclosure given below.

### BRIEF DESCRIPTION OF THE DRAWINGS

The accompanying drawings are included to provide a further understanding of the disclosure and are incorporated in and constitute a part of this specification. The drawings illustrate embodiments of the disclosure and, together with the description, serve to explain principles of the disclosure. In the drawings:

FIG. 1A is a schematic perspective view of a display apparatus according to an embodiment of the disclosure;

FIG. 1B is a schematic plan view of a display apparatus according to an embodiment of the disclosure;

FIG. 2A is a schematic plan view of a display apparatus according to an embodiment of the disclosure;

FIG. 2B is a schematic cross-sectional view of a display apparatus according to an embodiment of the disclosure;

FIG. 3A to FIG. 3C are schematic enlarged cross-sectional views showing parts of display apparatuses according to embodiments of the disclosure;

FIG. 4A is a schematic diagram showing a part of a quantum dot composition of an embodiment of the disclosure in more detail;

FIG. 4B schematically shows a quantum dot included in a quantum dot composition according to an embodiment of the disclosure;

FIG. 5 is a schematic cross-sectional view showing a part of a light controlling member according to an embodiment of the disclosure;

FIG. 6A is a schematic cross-sectional view showing a part of a light controlling member according to an embodiment of the disclosure;

FIG. 6B schematically shows a quantum dot and an additive, included in a light controlling member according to an embodiment of the disclosure;

FIG. 7A is a schematic flowchart showing a manufacturing method of a display apparatus according to an embodiment of the disclosure;

FIG. 7B is a schematic flowchart subdividing a forming step of a light controlling layer according to an embodiment of the disclosure;

FIG. 8A to FIG. 8C are schematic cross-sectional views showing some steps among the manufacturing method of a display apparatus according to an embodiment of the disclosure.

FIG. 9 is a diagram showing power conversion efficiency measured in accordance with time of display apparatuses according to the Example and Comparative Example; and

FIG. 10 is a diagram showing evaluation results on process maintenance rates of display apparatuses according to the Example and Comparative Example.

### DETAILED DESCRIPTION OF THE EMBODIMENTS

Hereinafter, embodiments of the disclosure will be explained referring to the drawings.

In the description, in case that an element (or a region, a layer, a part, etc.) is referred to as being “on”, “connected with” or “combined with” another element, it can be directly connected with/bonded on the other element, or intervening third elements may also be disposed.

Like reference numerals refer to like elements throughout. In the drawings, the thicknesses, ratios, and dimensions of elements may be exaggerated for effective explanation of technical contents. “and/or” may include one or more combinations that may define relevant elements.

It will be understood that, although the terms first, second, etc. may be used herein to describe various elements, these elements should not be limited by these terms. These terms are only used to distinguish one element from another element. For example, a first element could be termed a second element without departing from the scope of the disclosure. Similarly, a second element could be termed a first element. As used herein, the singular forms are intended to include the plural forms as well, unless the context clearly indicates otherwise.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The display surface may be parallel to a surface defined by a first direction DR1 and a second direction DR2. A normal direction of the display surface, i.e., a thickness direction of the display device DD, may indicate a third direction DR3. In this specification, an expression of “when viewed from a plane or on a plane” may represent a case when viewed in the third direction DR3. Hereinafter, a front surface (or a top surface) and a rear surface (or a bottom surface) of each of layers or units may be distinguished by the third direction DR3. However, directions indicated by the first to third directions DR1, DR2, and DR3 may be a relative concept, and converted with respect to each other, e.g., converted into opposite directions.

The term “overlap” or “at least partially overlap” as used herein may mean that at least part of a first object faces at least part of a second object in a given direction or given view.

The phrase “at least one of” is intended to include the meaning of “at least one selected from the group of” for the purpose of its meaning and interpretation. For example, “at least one of A and B” may be understood to mean “A, B, or A and B.”.

The terminology used herein is for the purpose of describing particular embodiments and is not intended to be limiting. As used herein, the singular forms, “a,” “an,” and “the” are intended to include the plural forms as well, unless the context clearly indicates otherwise.

It will be further understood that the terms “comprises” and/or “comprising,” when used in this specification, specify the presence of stated features, numerals, steps, operations, elements, parts, or the combination thereof, but do not preclude the presence or addition of one, or more other features, numerals, steps, operations, elements, parts, or the combination thereof.

In the description, when a layer, a film, a region, a plate, etc. is referred to as being “directly on” another part, it can mean no intervening layers, films, regions, plates, etc. are present. For example, being “directly on” may mean disposition without using an additional element such as an adhesive element between two layers or two elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements.

Unless otherwise defined or implied herein, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized, or overly formal sense unless expressly so defined herein.

Hereinafter, referring to the drawings, a quantum dot composition QCP, a display apparatus DD manufactured therefrom, and a manufacturing method of the display apparatus DD according to embodiments of the disclosure will be explained.

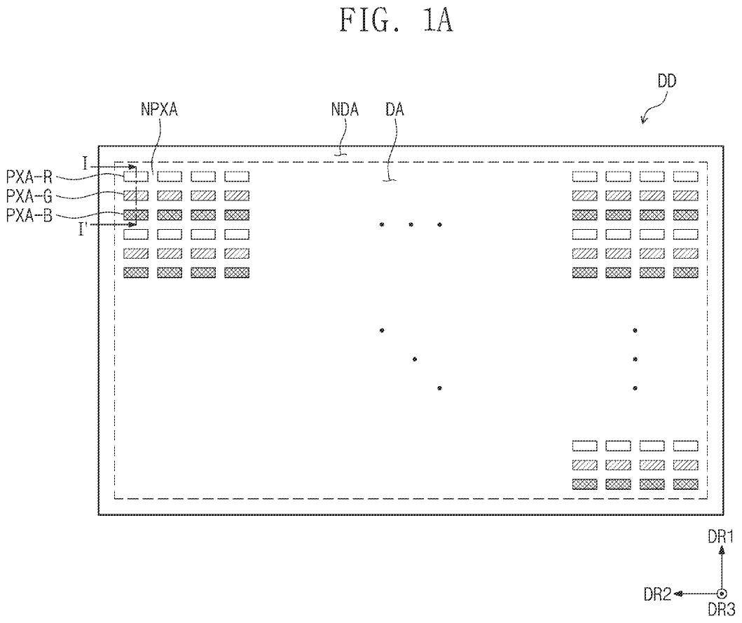

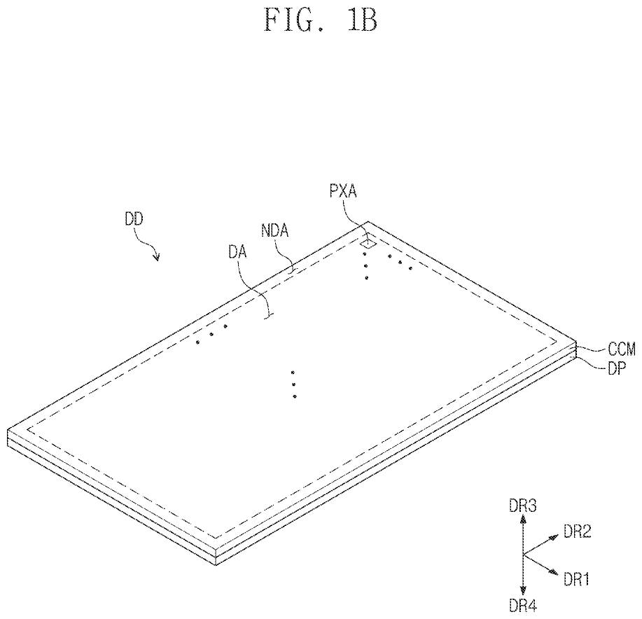

FIG. 1A is a schematic perspective view showing a display apparatus DD of an embodiment. FIG. 1B is a schematic plan view showing a display apparatus DD of an embodiment.

The display apparatus DD of an embodiment may be an apparatus which is activated according to electrical signals. For example, the display apparatus DD may be cellular phones, tablets, car navigations, game consoles, or wearable devices, but an embodiment of the disclosure is not limited thereto.

In FIG. 1A and the drawings below, at least one among a first direction DR1 to a fourth direction DR4 is shown, and the directions indicated by the first to fourth directions DR1, DR2, DR3, and DR4, explained in the description may have relative concept and may be changed into another directions.

In the description, the thickness direction of the display apparatus DD may be a direction parallel to the third direction DR3 which is a normal direction to a plane defined by the first direction DR1 and the second direction DR2. In the description, the front (or top) and the rear (or bottom) of the elements composing the display apparatus DD may be defined based on the third direction DR3.

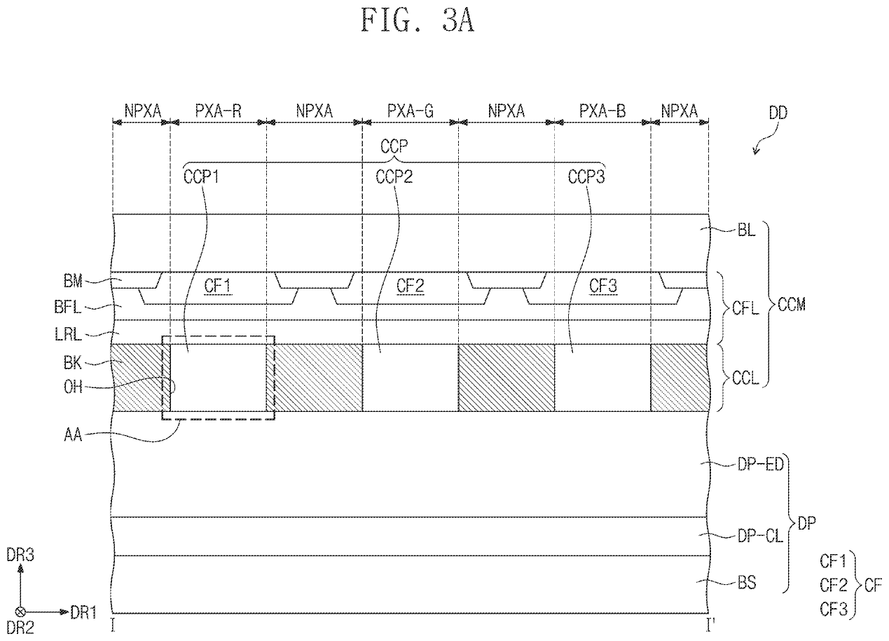

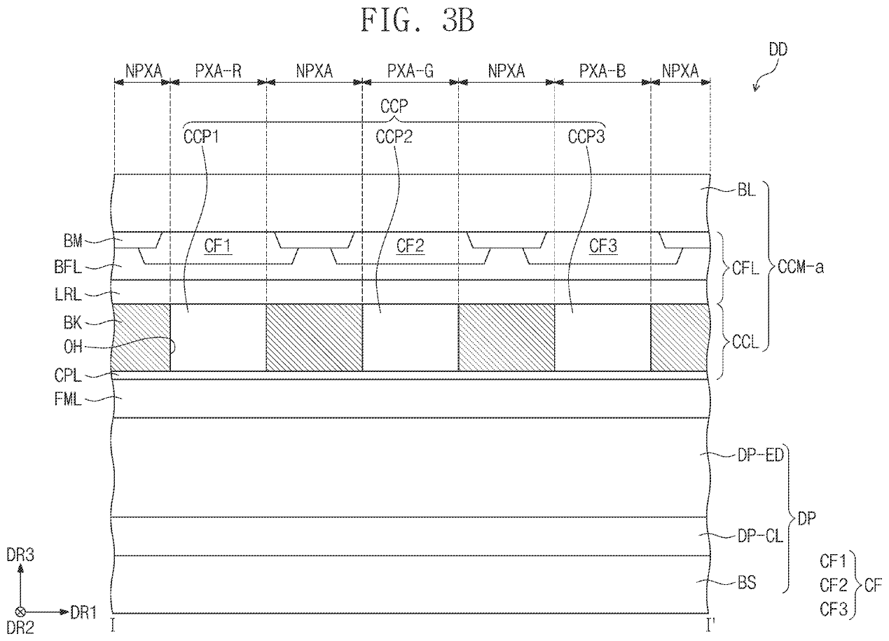

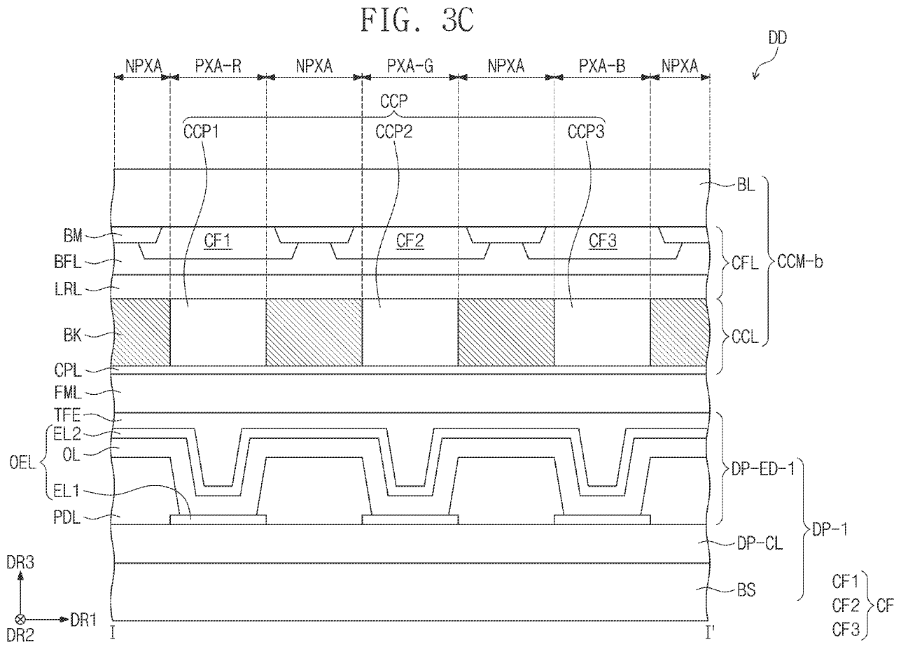

The display apparatus DD of an embodiment may include a display area DA and a non-display area NDA which is adjacent to the display area DA. The display area DA corresponds to a part displaying images. In the display area DA, multiple luminous areas PXA and a non-luminous area NPXA may be defined. The multiple luminous areas PXA may include first to third luminous areas PXA-R, PXA-G, and PXA-B, emitting lights in different wavelength regions. The non-luminous area NPXA may establish the boundaries of the first to third luminous areas PXA-R, PXA-G, and PXA-B. In the non-luminous area NPXA, a structure preventing the color mixing among the first to third luminous areas PXA-R, PXA-G, and PXA-B, for example, a partition (or bank) BK (see FIG. 3A to FIG. 3C) may be disposed.

Referring to FIG. 1A and FIG. 1B together, in the display apparatus DD of an embodiment, multiple luminous areas PXA may include three luminous areas PXA-R, PXA-G, and PXA-B, emitting red light, green light, and blue light. For example, the display apparatus DD of an embodiment may include a first luminous area PXA-R, a second luminous area PXA-G, and a third luminous area PXA-B, distinguished from each other.

In the display apparatus DD according to an embodiment, the luminous areas PXA-R, PXA-G, and PXA-B may be arranged in a stripe type. Referring to FIG. 1A, each of multiple first luminous areas PXA-R, multiple second luminous areas PXA-G, and multiple third luminous areas PXA-B may be arranged along the second direction DR2. In the first direction DR1, the first luminous area PXA-R, the second luminous area PXA-G, and the third luminous area PXA-B may be repeated in sequence.

In FIG. 1A, the areas of the luminous areas PXA-R, PXA-G, and PXA-B are shown similar, but an embodiment of the disclosure is not limited thereto, and the areas of the luminous areas PXA-R, PXA-G, and PXA-B may be different from each other according to the wavelength regions of light emitted. The areas of the luminous areas PXA-R, PXA-G, and PXA-B may mean areas in case that seen on a plane defined by the first direction DR1 and the second direction DR2.

The arrangement type of the luminous areas PXA-R, PXA-G, and PXA-B is not limited to that shown in FIG. 1A, and the arrangement sequence of the first luminous area PXA-R, the second luminous area PXA-G, and the third luminous area PXA-B may be combined in various types according to the properties of display quality required for the display apparatus DD. For example, the arrangement type of the luminous areas PXA-R, PXA-G, and PXA-B may be a pentile (PENTILE™) arrangement type or a diamond (Diamond Pixel™) arrangement type.

The areas of the luminous areas PXA-R, PXA-G, and PXA-B may be different from each other. For example, in an embodiment, the area of the second luminous area PXA-G may be smaller than the area of the third luminous area PXA-B, but an embodiment of the disclosure is not limited thereto.

Referring to FIG. 1A and FIG. 1B together, in an embodiment, the display area DA may have a square shape. The non-display area NDA may surround the display area DA. However, an embodiment of the disclosure is not limited thereto, and the shape of the display area DA and the shape of the non-display area NDA may be designed relatively. In an embodiment, the non-display area NDA may be omitted.

The display apparatus DD of an embodiment may include a display panel DP including a display device layer DP-ED (see FIG. 3A) and a light controlling member CCM including a light controlling layer CCL (see FIG. 3A).

The display panel DP may be an ultra compact light emitting device display panel DP including an ultra compact light emitting device. For example, the display panel DP may include a light emitting device, and the light emitting device may be a nano LED or a micro LED. However, an embodiment of the disclosure is not limited thereto, and the display panel DP included in the display apparatus DD may be an organic electroluminescence emitting display panel or a quantum dot emitting display panel.

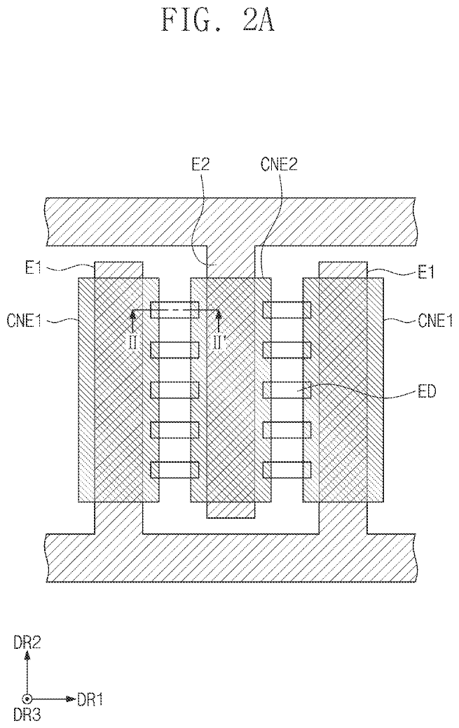

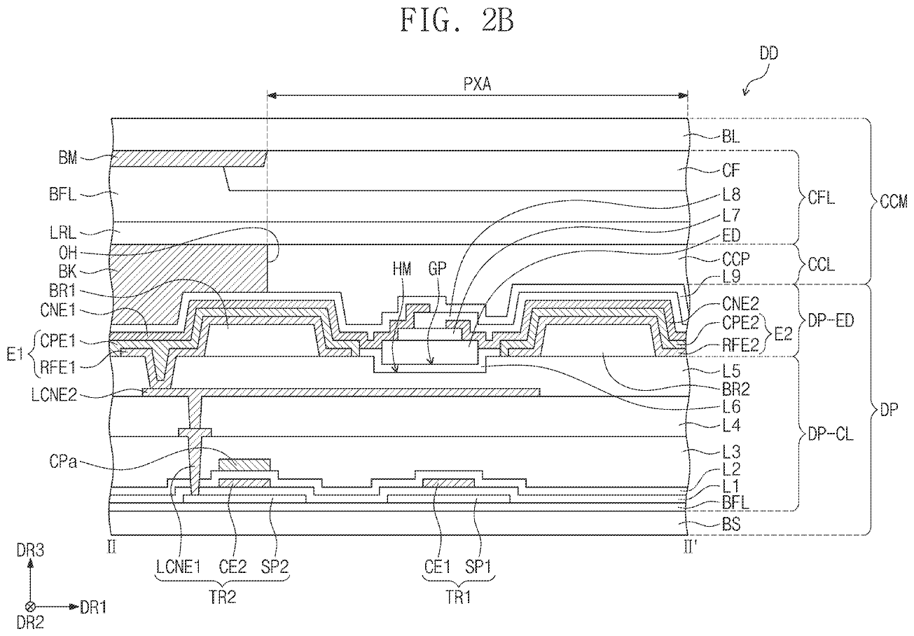

FIG. 2A is a schematic plan view of a part of a display apparatus DD according to an embodiment. FIG. 2B is a schematic cross-sectional view of a display apparatus DD according to an embodiment. For easy explanation, FIG. 2B shows a part including a luminous area PXA corresponding to one pixel, and some configurations are omitted. FIG. 2B may show the schematic cross-section of a part corresponding to line II-II′ of FIG. 2A.

Referring to FIG. 2A and FIG. 2B, the display apparatus DD of an embodiment may include the display panel DP and the light controlling member CCM disposed on the display panel DP. The display panel DP may include a base substrate BS, a circuit layer DP-CL disposed on the base substrate BS, and a display device layer DP-ED disposed on the circuit layer DP-CL.

In the display panel DP, the base substrate BS may be a member providing a base surface where the display device layer DP-ED is disposed. The base substrate BS may be a plastic substrate, an insulating film, or a stacked structure including multiple insulating layers. The base substrate BS may have a multi-layer structure. For example, the base substrate BS may have a three-layer structure of a polymer resin layer, a barrier layer, and a polymer resin layer. The polymer resin layer may include a polyimide-based resin. The base substrate BS may be a support layer formed using polyimide as a single layer.

The circuit layer DP-CL may be disposed on the base layer BS. The circuit layer DP-CL may include an insulating layer, a semiconductor pattern, a conductive pattern, a signal line, or the like. An insulating layer, a semiconductor layer, and a conductive layer may be formed on the base substrate BS by a method of coating, deposition, or the like, and the insulating layer, the semiconductor layer, and the conductive layer may be selectively patterned through multiple lithography processes. After that, the semiconductor pattern, the conductive pattern, and the signal line included in the circuit layer DP-CL may be formed.

The circuit layer DP-CL may include a thin film transistor formed on the base substrate BS and multiple insulating layers, and may also include multiple connecting electrode parts formed to penetrate the multiple insulating layers.

On the base substrate BS, a buffer layer BFL may be disposed. A first thin film transistor TR1 and a second thin film transistor TR2 may be disposed on the buffer layer BFL. The first thin film transistor TR1 may include a first control electrode CE1 and a first semiconductor pattern SP1. The second thin film transistor TR2 may include a second control electrode CE2, a first bottom connecting electrode LCNE1, and a second semiconductor pattern SP2.

The first semiconductor pattern SP1 and the second semiconductor pattern SP2 may be disposed on the buffer layer BFL. The buffer layer BFL may provide the first semiconductor pattern SP1 and the second semiconductor pattern SP2 with modified surfaces. The first semiconductor pattern SP1 and the second semiconductor pattern SP2 may have stronger adhesiveness with respect to the buffer layer BFL in case of being formed directly on the base substrate BS. In an embodiment, the buffer layer BFL may be a barrier layer protecting each bottom of the first semiconductor pattern SP1 and the second semiconductor pattern SP2. The buffer layer BFL may block a penetration of contaminants or moisture of the base substrate BS itself or inflowing through the base substrate BS into the first semiconductor pattern SP1 and the second semiconductor pattern SP2.

A first insulating layer L1 may be disposed on the buffer layer BFL and may cover the first semiconductor pattern SP1 and the second semiconductor pattern SP2. The first insulating layer L1 may include an inorganic material and may have a single layer or a multi-layer structure. The first insulating layer L1 may include at least one among aluminum oxide, titanium oxide, silicon oxide, silicon nitride, silicon oxynitride, zirconium oxide, and hafnium oxide, or a combination thereof. The first control electrode CE1 and the second control electrode CE2 may be disposed on the first insulating layer L1. A second insulating layer L2 may be disposed on the first insulating layer L1 and may cover the first control electrode CE1 and the second control electrode CE2. The second insulating layer L2 may include an inorganic material.

A capacitor (not shown) may include a first cap electrode (not shown) and a second cap electrode CPa. For example, the first cap electrode may be branched from the second control electrode CE2, and the second cap electrode CPa may be disposed on the second insulating layer L2.

A third insulating layer L3 may be disposed on the second insulating layer L2 and may cover the second cap electrode CPa. On the third insulating layer L3, a first bottom connecting electrode LCNE1 connected with the second semiconductor pattern SP2 may be disposed. The first thin film transistor TR1 and the second thin film transistor TR2 may further include an input electrode and an output electrode disposed on the third insulating layer L3 and connected with the first semiconductor pattern SP1 and the second semiconductor pattern SP2, respectively, via through holes penetrating first to third insulating layers L1, L2, and L3. On the third insulating layer L3, signal wirings, for example, at least a portion of each of scan lines and data lines may be disposed.

A fourth insulating layer L4 may be disposed on the third insulating layer L3 and may cover the first bottom connecting electrode LCNE1. The fourth insulating layer L4 may include an inorganic material and/or an organic material and may have a single layer or a multi-layer structure. On the fourth insulating layer L4, a second bottom connecting electrode LCNE2 may be disposed. On the fourth insulating layer L4, signal wings, for example, at least another portion of each of scan lines and data lines may be disposed as well as the second bottom connecting electrode LCNE2. The second bottom connecting electrode LCNE2 may be connected with the first bottom connecting electrode LCNE1.

A fifth insulating layer L5 may be disposed on the fourth insulating layer L4 and may cover the second bottom connecting electrode LCNE2. The fifth insulating layer L5 may include an organic material. The fifth insulating layer L5 may cover a pixel circuit (not shown) disposed thereunder and may provide at least a portion of a planar surface. For example, the fifth insulating layer L5 may provide a region excluding a region where a groove HM is defined, a planar surface. However, this is merely an embodiment, and the groove HM may not be defined in the fifth insulating layer L5.

A first partition (or first bank) BR1 and a second partition (or second bank) BR2 may be disposed on the fifth insulating layer L5. The first partition BR1 and the second partition BR2 may be separated in the first direction DR1. Each of the first partition BR1 and the second partition BR2 may include an organic material.

The first electrode E1 may cover the first partition BR1, and the second electrode E2 may cover the second partition BR2. For example, between the first electrode E1 and the fifth insulating layer L5, the first partition BR1 may be disposed, and between the second electrode E2 and the fifth insulating layer L5, the second partition BR2 may be disposed.

In the fifth insulating layer L5, a through hole may be provided, and by the through hole, the second bottom connecting electrode LCNE2 may be exposed. The first electrode E1 may be electrically connected with the exposed second bottom connecting electrode LCNE2. Though not shown, the second electrode E2 may be electrically connected with a second power source line (not shown). For example, to the second electrode E2, a second power voltage (not shown) may be provided.

The first electrode E1 may include a first reflective electrode RFE1 and a first capping electrode CPE1, and the second electrode E2 may include a second reflective electrode RFE2 and a second capping electrode CPE2.

Each of the first reflective electrode RFE1 and the second reflective electrode RFE2 may include a reflective material. Each of the first reflective electrode RFE1 and the second reflective electrode RFE2 may have a single layer structure or a stacked structure of multiple layers. For example, each of first reflective electrode RFE1 and the second reflective electrode RFE2 may have a stacked structure of indium tin oxide (ITO), silver (Ag), and indium tin oxide (ITO) in order.

The first capping electrode CPE1 may cap the first reflective electrode RFE1, and the second capping electrode CPE2 may cap the second reflective electrode RFE2. For example, each of the first capping electrode CPE1 and the second capping electrode CPE2 may include at least one among indium zinc oxide (IZO), indium tin oxide (ITO), indium gallium oxide (IGO), indium zinc gallium oxide (IGZO), and the mixtures/compounds thereof.

On a plane, in a region of the fifth insulating layer L5 between the first electrode E1 and the second electrode E2, a groove HM may be provided. In case that seen from a third direction DR3, the groove HM may be non-overlapped with the first electrode E1 and the second electrode E2.

A sixth insulating layer L6 may be disposed on the groove HM. The sixth insulating layer L6 may include an inorganic material. In the sixth insulating layer L6, a bent part GP may be provided in a region corresponding to the groove HM. For example, the groove HM and the bent part GP may be overlapped on a plane. In an embodiment of the disclosure, the groove HM may not be provided. In the sixth insulating layer L6, the bent part GP may not be provided.

A light emitting device ED may be provided on the sixth insulating layer L6. The light emitting device ED may be disposed between the first electrode E1 and the second electrode E2. The light emitting device ED may be electrically connected with the first electrode E1 and the second electrode E2. The light emitting device ED may be disposed between the first partition BR1 and the second partition BR2. For example, the light emitting device ED may be disposed in the groove HM and the bent part GP.

The light emitting device ED may include an n-type semiconductor layer, a p-type semiconductor layer, and an active layer disposed between the n-type semiconductor layer and the p-type semiconductor layer. The light emitting device ED may have various shapes such as a cylinder shape and a polygonal shape. In the light emitting device ED, the n-type semiconductor layer may be connected with any one among the first electrode E1 and the second electrode E2, and the p-type semiconductor layer may be connected with the other one among the first electrode E1 and the second electrode E2. The active layer may be formed into at least one among a single quantum well structure, a multi quantum well structure, a quantum line structure, and a quantum dot structure. The active layer may be a region where electrons injected through the n-type semiconductor layer and holes injected from the p-type semiconductor layer are recombined.

Referring to FIG. 2A, in the display apparatus DD of an embodiment, each of the first electrode E1 and the second electrode E2 may be extended in the second direction DR2, and the first electrode E1 and the second electrode E2 may be separated from each other in the first direction DR1. FIG. 2A is merely an embodiment, and the disclosure is not limited thereto. The first electrode E1 and the second electrode E2 may be modified into various structures without limitation if separated from each other. In FIG. 2A, a diagram in which two first electrodes E1 are provided with the second electrode E2 extended in the second direction DR2 therebetween, is shown as an embodiment.

On a plane, the light emitting device ED may be disposed between the first electrode E1 and the second electrode E2, and the light emitting device ED may be non-overlapped with the first electrode E1 and the second electrode E2. Multiple light emitting devices ED may be provided, and the multiple light emitting devices may be connected in parallel. The light emitting device ED may be electrically connected with the first electrode E1 by the first connecting electrode CNE1 and may be electrically connected with the second electrode E2 by the second connecting electrode CNE2.

Referring to FIG. 2B again, on the light emitting device ED, a seventh insulating layer L7 (or insulating pattern) may be disposed. The seventh insulating layer L7 may cover at least a portion of the top of the light emitting device ED.

The second connecting electrode CNE2 may be disposed on the seventh insulating layer L7, the light emitting device ED, the sixth insulating layer L6, and the second electrode E2. An eighth insulating layer L8 may be disposed on the second connecting electrode CNE2 and the seventh insulating layer L7. The first connecting electrode CNE1 may be disposed on the eighth insulating layer L8, the seventh insulating layer L7, the light emitting device ED, the sixth insulating layer L6, and the first electrode E1. Though a length of the light emitting device is hundreds of micrometers or less, the second connecting electrode CNE2 and the first connecting electrode CNE1 may not make direct contact due to the eighth insulating layer L8. However, this is merely an embodiment of the disclosure, and in another embodiment of the disclosure, the first connecting electrode CNE1 and the second connecting electrode CNE2 may be formed simultaneously by a same process.

The first connecting electrode CNE1 and the second connecting electrode CNE2 may include a conductive material. For example, the conductive material may include at least one among indium zinc oxide (IZO), indium tin oxide (ITO), indium gallium oxide (IGO), indium zinc gallium oxide (IGZO), and the mixtures/compounds thereof. However, an embodiment of the disclosure is not limited thereto. For example, the conductive material may be a metal material, and the metal material may include, for example, molybdenum, silver, titanium, copper, aluminum, or alloys thereof.

A ninth insulating layer L9 may be disposed on the first connecting electrode CNE1 and the eighth insulating layer L8. The ninth insulating layer L9 may be an encapsulating layer sealing the light emitting device ED and blocking moisture and oxygen.

A light controlling member CCM may include a base layer BL and a light controlling layer CCL. The light controlling layer CCL may include a photoconverter. The photoconverter may be a quantum dot or a phosphor. The photoconverter may convert the wavelength of light provided to emit. For example, the light controlling layer CCL may be a layer including the quantum dots or a layer including the phosphors.

The light controlling layer CCL may include multiple light controlling parts CCP (e.g., including first, second, and third light controlling parts CCP1, CCP2, and CCP3). The light controlling layer CCL may include the multiple light controlling parts CCP separated from each other and partition patterns (or bank patterns) disposed among the separated multiple light controlling parts CCP. The multiple light controlling parts CCP may be disposed (e.g., disposed directly) on a display device layer DP-ED. The multiple light controlling parts CCP may be disposed directly on the display device layer DP-ED. The multiple light controlling parts CCP may be disposed (e.g., disposed directly) on the ninth insulating layer L9 of the display device layer DP-ED.

The light controlling member CCM according to an embodiment may further include a color filter layer CFL. The color filter layer CFL may be disposed between the base layer BL and the light controlling layer CCL. The color filter layer CFL may include a light blocking part BM and a filter part CF. On a side of the base layer BL facing the base substrate BS, the light blocking part BM may be disposed. In the light blocking part BM, an opening part may be provided, and the color part CF may cover the opening part. A region exposed by the opening part may correspond to a luminous area PXA.

In an embodiment, the light controlling member CCM may include the base layer BL disposed on the color filter layer CFL. The base layer BL may be a member providing a base surface for disposing the light controlling layer CCL or the like. The base layer BL may be a glass substrate, a metal substrate, a plastic substrate, or the like. However, an embodiment of the disclosure is not limited thereto, and the base layer BL may be an inorganic layer, an organic layer, or a composite material layer. Unlike the drawing, in an embodiment, the base layer BL may be omitted.

FIG. 3A is a schematic enlarged cross-sectional view showing a part of a display apparatus DD according to an embodiment of the disclosure. FIG. 3A shows a part corresponding to line I-I′ of FIG. 1A.

The display apparatus DD according to an embodiment may include a display panel DP and a light controlling member CCM disposed on the display panel DP, and the light controlling member CCM may include a light controlling layer CCL and a color filter layer CFL. The light controlling member CCM may include a base layer BL, the light controlling layer CCL disposed under the base layer BL, and the color filter layer CFL disposed between the light controlling layer CCL and the base layer BL. In the light controlling member CCM, the light controlling layer CCL may be disposed adjacent to the display panel DP.

Referring to FIG. 3A, the display apparatus DD may include a non-luminous area NPXA and luminous areas PXA-R, PXA-G, and PXA-B. Each of the luminous areas PXA-R, PXA-G, and PXA-B may be an area emitting light produced in a light emitting device ED included in a display device layer DP-ED (see FIG. 2B). The areas of the luminous areas PXA-R, PXA-G, and PXA-B may be different from each other, and the area may mean an area when seen on a plane (or in a plan view). In order to avoid the repetitive explanation(s), a configuration of the display device layer DP-ED is omitted and shown in FIG. 3A. A detailed structure of the display device layer DP-ED refers to FIG. 2B.

The luminous areas PXA-R, PXA-G, and PXA-B may be classified into multiple groups according to the color of light. In the display apparatus DD of an embodiment, shown in FIG. 3A, three luminous areas PXA-R, PXA-G, and PXA-B, emitting red light, green light, and blue light may be shown as an embodiment. For example, the display apparatus DD of an embodiment may include a red luminous area PXA-R, a green luminous area PXA-G, and a blue luminous area PXA-B, separated from each other.

In the display apparatus DD of an embodiment, shown in FIG. 3A, the display panel DP may emit light in equal to wavelength region each other irrespective of the luminous areas PXA-R, PXA-G, and PXA-B of the display apparatus DD. For example, the display panel DP may provide the light controlling member CCM with blue light which is first color light.

In the display apparatus DD of an embodiment, shown in FIG. 3A, the luminous areas PXA-R, PXA-G, and PXA-B are shown to have the same area, but are not limited thereto, and the luminous areas PXA-R, PXA-G, and PXA-B may be provided to have various areas. For example, the red luminous area PXA-R and the green luminous area PXA-G among the luminous areas PXA-R, PXA-G, and PXA-B may have the same area, and the blue luminous area PXA-B may have a smaller area than the red luminous area PXA-R and the green luminous area PXA-G. However, an embodiment of the disclosure is not limited thereto, and each of the luminous areas PXA-R, PXA-G, and PXA-B may have various areas according to the color emitted from the light controlling parts CCP1, CCP2, and CCP3. For example, in the display apparatus DD of an embodiment, the blue luminous area PXA-B may have the largest area, and the green luminous area PXA-G may have the smallest area. However, an embodiment of the disclosure is not limited thereto, and the luminous areas PXA-R, PXA-G, and PXA-B may emit light of different color from red light, blue light, and green light, or the luminous areas PXA-R, PXA-G, and PXA-B may be provided with a different area ratio.

Referring to FIG. 3A, the display panel DP according to an embodiment may include a base substrate BS, a circuit layer DP-CL disposed on the base substrate BS, and a display device layer DP-ED disposed on the circuit layer DP-CL. For the display panel DP included in the display apparatus DD of an embodiment, shown in FIG. 3A, a same explanation referring to FIG. 2A and FIG. 2B may be applied.

The light controlling layer CCL may be disposed (e.g., disposed directly) on the display panel DP. The light controlling layer CCL may be disposed directly on the display panel DP. The light controlling layer CCL may be disposed (e.g., disposed directly) on the display device layer DP-ED. The light controlling layer CCL may be disposed on a same substrate as the display device layer DP-ED, for example, the base substrate BS. Accordingly, the light controlling layer CCL and the display panel DP may be formed through a continuous process without a separate bonding process.

The light controlling layer CCL may include separately disposed multiple partitions BK and multiple light controlling parts CCP disposed among the partitions BK. The partitions BK may define an opening part OH exposing a side of the color filter layer CFL disposed to overlap the light controlling layer CCL in a plan view. The light controlling parts CCP1, CCP2, and CCP3 may fill up the opening OH. For example, the light controlling member CCM according to an embodiment may include the base layer BL, multiple partitions BK disposed on the base layer BL, and first to third light controlling parts CCP1, CCP2, and CCP3 disposed among the separately disposed multiple partitions BK.

In the display apparatus DD of an embodiment, at least one among the multiple light controlling parts CCP1, CCP2, and CCP3, which are included in the light controlling layer CCL may be formed from a quantum dot composition QCP of an embodiment. For example, the first light controlling part CCP1 and the second light controlling part CCP2 among the multiple light controlling parts CCP1, CCP2, and CCP3, which are included in the light controlling layer CCL may be formed from the quantum dot composition QCP of an embodiment. However, an embodiment of the disclosure is not limited thereto, and the multiple light controlling parts CCP1, CCP2, and CCP3 all may be formed from the quantum dot composition QCP of an embodiment, or at least one among the multiple light controlling parts CCP1, CCP2, and CCP3 may be formed from the quantum dot composition QCP of an embodiment. Detailed explanation on the quantum dot composition QCP according to an embodiment will be given below.

The light controlling member CCM of an embodiment may include the multiple light controlling parts CCP (e.g., CCP1, CCP2, and CCP3). The multiple light controlling parts CCP may include the first light controlling part CCP1 for converting first light into second light, the second light controlling part CCP2 for converting the first light into third light, and the third light controlling part CCP3 for transmitting the first light. The third light may be light in a longer wavelength region than the first light, and the second light may be light in a longer wavelength region than the first light and the third light. For example, the first light may be blue light, the second light may be red light, and the third light may be green light. The first light may be light in a wavelength region of about 410 nm to about 480 nm, the second light may be light in a wavelength region of about 625 nm to about 675 nm, and the third light may be light in a wavelength region of about 500 nm to about 570 nm. The first light may be source light provided from the display panel DP to the light controlling parts CCP.

The third light controlling part CCP3 may be a transmitting part not for converting the wavelength of but for transmitting the first light. In the first light controlling part CCP1 and the second light controlling part CCP2, a luminous body may be included. The luminous body may be a particle converting the wavelength of incident light to emit light having a different wavelength. In an embodiment, the luminous body included in the first light controlling part CCP1 and the second light controlling part CCP2 may be a quantum dot. However, an embodiment of the disclosure is not limited thereto, and the luminous body may also be included in the third light controlling part CCP3.

The quantum dot may be a particle for converting the wavelength of light provided. The core of the quantum dot may be selected from a II-VI group compound, a III-VI group compound, a group compound, a III-V group compound, a III-II-V group compound, a IV-VI group compound, a IV group element, a IV group compound, and combinations thereof.

The II-VI group compound may be selected from the group consisting of: a binary compound selected from the group consisting of CdSe, CdTe, CdS, ZnS, ZnSe, ZnTe, ZnO, HgS, HgSe, HgTe, MgSe, MgS, and mixtures thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and mixtures thereof; and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and mixtures thereof.

The III-VI group compound may include a binary compound such as In₂S₃, In₂Se₃, or the like, a ternary compound such as InGaS₃, InGaSe₃, or the like, or optional combinations thereof.

The group compound may be selected from a ternary compound selected from the group consisting of AgInS, AgInS₂, CuInS, CuInS₂, AgGaS₂, CuGaS₂, CuGaO₂, AgGaO₂, AgAlO₂, and mixtures thereof, or a quaternary compound such as AgInGaS₂, CuInGaS₂, or the like.

The III-V group compound may be selected from the group consisting of: a binary compound selected from the group consisting of GaN, GaP, GaAs, GaSb, AlN, AlP, AlAs, AlSb, InN, InP, InAs, InSb, and mixtures thereof; a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and mixtures thereof; and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and mixtures thereof. The III-V group compound may further include a II group metal. For example, InZnP, etc. may be selected as a III-II-V group compound.

The IV-VI group compound may be selected from the group consisting of: a binary compound selected from the group consisting of SnS, SnSe, SnTe, PbS, PbSe, PbTe, and mixtures thereof; a ternary compound selected from the group consisting of SnSeS, SnSeTe, SnSTe, PbSeS, PbSeTe, PbSTe, SnPbS, SnPbSe, SnPbTe, and mixtures thereof; and a quaternary compound selected from the group consisting of SnPbSSe, SnPbSeTe, SnPbSTe, and mixtures thereof.

The IV group element may be selected from the group consisting of Si, Ge, and a mixture thereof.

The IV group compound may be a binary compound selected from the group consisting of SiC, SiGe, and a mixture thereof.

The binary compound, the ternary compound, or the quaternary compound may be present at uniform concentration in a particle or may be present at a partially different concentration distribution state in a same particle. A core/shell structure in which a quantum dot wraps another quantum dot may be possible. The core/shell structure may have a concentration gradient in which the concentration of an element present in the shell is decreased toward the core.

In some embodiments, the quantum dot may have the above-described core/shell structure including a core including a nanocrystal and a shell wrapping the core. The shell of the quantum dot may play a role of a protective layer for preventing the chemical deformation of the core to maintain semiconductor properties and/or a charging layer for imparting the quantum dot with electrophoretic properties. The shell may have a single layer or a multilayer. Examples of the shell of the quantum dot may include a metal oxide, a non-metal oxide, a semiconductor compound, or combinations thereof.

For example, the metal oxide or the non-metal oxide may include a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, or the like, or a ternary compound such as MgAl₂O₄, CoFe₂O₄, NiFe₂O₄, CoMn₂O₄, or the like, but an embodiment of the disclosure is not limited thereto.

Also, the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but an embodiment of the disclosure is not limited thereto.

The quantum dot may have a full width of half maximum (FWHM) of emission wavelength spectrum in a range of about 45 nm or less, about 40 nm or less, more about 30 nm or less. Within the range, color purity or color reproducibility may be improved. Light emitted via such quantum dot is emitted in all directions, and light view angle properties may be improved.

A shape of the quantum dot may be a generally used shape in the art, without specific limitation. The quantum dot may have a structure such as nanoparticle, nanotube, nanowire, nanofiber, nanoplate particle, or the like. The shape of the quantum dot may be spherical, pyramidal, multi-arm, cubic, or the like.

The quantum dot may control a color of the light emitted according to a particle size, and accordingly, the quantum dot may have various emission colors such as blue, red, green, or the like. If the particle size of the quantum dot decreases, light of a short wavelength region may be emitted. For example, the particle size of the quantum dot emitting green light may be smaller than the particle size of the quantum dot emitting red light.

Though not shown, the multiple light controlling parts CCP1, CCP2, and CCP3 may further include an inorganic material. The inorganic material included in the multiple light controlling parts CCP1, CCP2, and CCP3 may be, for example, scattering particles. The scattering particles may be TiO₂ or silica-based nanoparticles, or the like. The scattering particles may be particles scattering light to increase light emitting efficiency. The scattering particles may be dispersed uniformly in the multiple light controlling parts CCP1, CCP2, and CCP3.

Referring to FIG. 3A again, the light controlling member CCM according to an embodiment may further include the color filter layer CFL. The color filter layer CFL may be disposed between the base layer BL and the light controlling layer CCL. The color filter layer CFL may include a light blocking part BM and a filter part CF.

The light blocking part BM may be disposed on (or under) the base layer BL. Multiple light blocking parts BM may be separately disposed from each other, while exposing a portion of the base layer BL (or filter part CF). Among the light blocking parts BM, filters CF1, CF2, and CF3 may be disposed.

The filter part CF may include multiple filters CF1, CF2, and CF3. For example, the color filter layer CFL may include a first filter CF1 transmitting the second light, a second filter CF2 transmitting the third light, and a third filter CF3 transmitting the first light. For example, the first filter CF1 may be a red filter, the second filter CF2 may be a green filter, and the third filter CF3 may be a blue filter.

Each of the filters CF1, CF2, and CF3 may include a polymer photosensitive resin and a pigment or dye. The first filter CF1 may include a red pigment or dye, the second filter CF2 may include a green pigment or dye, and the third filter CF3 may include a blue pigment or dye.

An embodiment of the disclosure is not limited thereto, and the third filter CF3 may not include the pigment or dye. The third filter CF3 may include the polymer photosensitive resin and may not include the pigment or dye. The third filter CF3 may be transparent. The third filter CF3 may be formed using a transparent photosensitive resin.

The light blocking part BM may be a black matrix. The light blocking part BM may be formed by including an organic light blocking material or an inorganic light blocking material including a black pigment or dye. The light blocking part BM may prevent light leak phenomenon and may divide the boundaries among adjacent filters CF1, CF2, and CF3.

Multiple light blocking parts BM may be separately disposed, and each of the light blocking parts BM may be overlapped corresponding to each of the multiple partitions BK, respectively in a plan view.

The color filter layer CFL may further include a low refractive layer LRL. The low refractive layer LRL may be disposed between the filter part CF and the light controlling layer CCL. A refractive index of the low refractive layer LRL may be from about 1.1 to about 1.5. The refractive index value of the low refractive layer LRL may be controlled by a ratio of hollow inorganic particles and/or voids, or the like included in the low refractive layer LRL.

The color filter layer CFL may further include a buffer layer BFL. As shown in FIG. 3A, the buffer layer BFL may be shown to be disposed between the filter part CF and the low refractive layer LRL, but an embodiment of the disclosure is not limited thereto. For example, the buffer layer BFL may be disposed adjacent to the light controlling layer CCL. For example, the buffer layer BFL may be a plugging layer filling up between the low refractive layer LRL and the light controlling layer CCL. The buffer layer BFL may be a protective layer protecting the low refractive layer LRL or the filter part CF. The buffer layer BFL may be an inorganic material layer including at least one inorganic material among silicon nitride, silicon oxide, and silicon oxynitride. The buffer layer BFL may be formed as a single layer or multiple layers. However, an embodiment of the disclosure is not limited thereto, and some of the buffer layer BFL, the low refractive layer LRL, the light blocking part BM, and the filter parts CF1, CF2, and CF3, included in the color filter layer CFL may be omitted.

The base layer BL may be a member providing a base side where the color filter layer CFL or the like is disposed. The base layer BL may be a glass substrate, a metal substrate, a plastic substrate, or the like. However, an embodiment of the disclosure is not limited thereto, and the base layer BL may be an inorganic layer, an organic layer, or a composite material layer.

FIG. 3B is a schematic enlarged cross-sectional view of a display apparatus DD according to an embodiment of the disclosure. Hereinafter, in the explanation on the display apparatus DD according to an embodiment of the disclosure, referring to FIG. 3B, a same reference symbols are provided for the above-described elements in FIG. 2A to FIG. 3A, and detailed explanation thereon will be omitted.

Referring to FIG. 3B, in case that compared to the display apparatus DD shown in FIG. 3A, in the display apparatus DD according to an embodiment, a light controlling layer CCL may further include a capping layer CPL, and the display apparatus DD may further include a plugging layer FML disposed between a light controlling member CCM-a and a display panel DP. However, an embodiment of the disclosure is not limited thereto, and one among the capping layer CPL and the plugging layer FML may be omitted.

The display apparatus DD of an embodiment may include the display panel DP and the light controlling member CCM-a disposed on the display panel DP and may include the plugging layer FML disposed between the display panel DP and the light controlling member CCM-a.

The light controlling member CCM-a may include the light controlling layer CCL and a color filter layer CFL. The light controlling member CCM-a may include a base layer BL, the color filter layer CFL disposed under the base layer BL, and the light controlling layer CCL disposed under the color filter layer CFL. In the light controlling member CCM-a, the light controlling layer CCL may include the capping layer CPL disposed under multiple light controlling parts CCP1, CCP2, and CCP3.

The capping layer CPL may be disposed under (or on) the multiple light controlling parts CCP and the partition BK. The capping layer CPL may play a role of blocking a penetration of moisture and/or oxygen (hereinafter, will be referred to as “moisture/oxygen”). The capping layer CPL may be disposed under (or on) the multiple light controlling parts CCP to block the exposure of the multiple light controlling parts CCP to moisture/oxygen. The capping layer CPL may include at least one inorganic layer. For example, the capping layer CPL may be formed by including an inorganic material. For example, the capping layer CPL may be formed by including silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, or a metal thin film securing light transmittance. The capping layer CPL may further include an organic layer. The capping layer CPL may be composed of a single layer or multiple layers. As shown in FIG. 3B, the capping layer CPL may be disposed under the multiple light controlling parts CCP, for example, between the plugging layer FML and the multiple light controlling parts CCP, as an embodiment, but an embodiment of the disclosure is not limited thereto, and the capping layer CPL may also be disposed between the multiple light controlling parts CCP and the low refractive layer LRL.

The plugging layer FML may fill up between the display panel DP and the light controlling member CCM-a. The plugging layer FML may be disposed between the display panel DP and the light controlling layer CCL. For example, the light controlling layer CCL of the display apparatus DD, shown in FIG. 3B may not be disposed directly on the display panel DP but may be separated with the plugging layer FML therebetween, different from the light controlling layer CCL of the display apparatus DD shown in FIG. 3A.

The plugging layer FML may play a role of a buffer between the display panel DP and the light controlling member CCM-a. In an embodiment, the plugging layer FML may play a role of absorbing impact and increasing the intensity of the display apparatus DD. The plugging layer FML may be formed from a plugging resin including a polymer resin. For example, the plugging layer FML may be formed from the plugging resin including an acrylic resin, an epoxy-based resin, or the like.

The plugging layer FML may be an element distinguished from the capping layer CPL, and each of the plugging layer FML and the capping layer CPL may be formed in a separate process step. The plugging layer FML and the capping layer CPL may be formed using different materials from each other.

As described in FIG. 3A, in the display apparatus DD of an embodiment, shown in FIG. 3B, at least one among multiple light controlling parts CCP1, CCP2, and CCP3, included in the light controlling layer CCL may be formed from the quantum dot composition QCP of an embodiment.

For the display panel DP included in the display apparatus DD of an embodiment, shown in FIG. 3B, a same explanation referring to FIG. 2A and FIG. 2B will be applied.

FIG. 3C is a schematic enlarged cross-sectional view showing a part of a display apparatus DD according to an embodiment of the disclosure. Hereinafter, in the explanation on the display apparatus DD according to an embodiment of the disclosure, referring to FIG. 3C, a same reference symbols are provided for the above-described elements in FIG. 2A to FIG. 3B, and detailed explanation thereon will be omitted.

Referring to FIG. 3C, in case that compared to the display apparatus DD shown in FIG. 3A, in the display apparatus DD according to an embodiment, a structure of a display device layer DP-ED-1 may be different. A display panel DP-1 included in the display apparatus DD of an embodiment, shown in FIG. 3C may be an organic electroluminescence emitting display panel or a quantum dot emitting display panel, different from the display panel DP of the display apparatus DD shown in FIG. 3A. Hereinafter, the display panel DP-1 is shown as the organic electroluminescence emitting display panel, but the display panel DP-1 of an embodiment may be the quantum dot emitting display panel, and a same explanation on the display panel DP-1, which will be given below, may be applied except for using quantum dots as a luminous body.

The display apparatus DD according to an embodiment may include the display panel DP-1 and a light controlling member CCM-b disposed on the display panel DP-1. A same explanation referring to FIG. 3B, or the like may be applied to the light controlling member CCM-b included in the display apparatus DD of an embodiment, explained referring to FIG. 3C. For example, in the light controlling member CCM-b of the display apparatus DD of an embodiment, shown in FIG. 3C, a light controlling layer CCL may include a capping layer CPL as in the light controlling member CCM-a of the display apparatus DD of an embodiment, shown in FIG. 3B. The display apparatus DD shown in FIG. 3C may include a plugging layer FML disposed between the light controlling member CCM-b and the display panel DP-1, as in the display apparatus DD shown in FIG. 3B.

The display panel DP-1 according to an embodiment may include a base substrate BS, a circuit layer DP-CL disposed on the base substrate BS, and the display device layer DP-ED-1 disposed on the circuit layer DP-CL. The display device layer DP-ED-1 may include a pixel definition layer PDL, an organic electroluminescence device OEL disposed on and/or between the pixel definition layer PDL, and a thin film encapsulating layer TFE disposed on the organic electroluminescence device OEL.

The pixel definition layer PDL may be formed using a polymer resin. For example, the pixel definition layer PDL may be formed by including a polyacrylate-based resin or a polyimide-based resin. The pixel definition layer PDL may be formed by further including an inorganic material (in addition to the polymer resin). The pixel definition layer PDL may be formed by including a light absorbing material or may be formed by including a black pigment or a black dye. The pixel definition layer PDL may be formed using the inorganic material. For example, the pixel definition layer PDL may be formed by including silicon nitride (SiNₓ), silicon oxide (SiOₓ), silicon oxynitride (SiOₓN_{y}), or the like, or a combination thereof. The pixel definition layer PDL may define luminous areas PXA-R, PXA-G, and PXA-B. By the pixel definition layer PDL, the luminous areas PXA-R, PXA-G, and PXA-B and a non-luminous area NPXA may be distinguished.

The pixel definition layer PDL may be overlapped with a partition BK in a plan view. For example, multiple pixel definition layers PDL may be overlapped correspondingly to multiple partitions BK, respectively in a plan view.

The organic electroluminescence device OEL may include a first electrode EL1, a second electrode EL2 oppositely disposed to the first electrode EL1, and an organic layer OL disposed between the first electrode EL1 and the second electrode EL2. The organic layer OL may include a hole transport region, an emission layer, and an electron transport region. The hole transport region may include a hole injection layer adjacent to the first electrode EL1 and a hole transport layer disposed between the hole injection layer and the emission layer, and the electron transport region may include an electron injection layer adjacent to the second electrode EL2 and an electron transport layer disposed between the emission layer and the electron injection layer.

On the organic electroluminescence device OEL, a thin film encapsulating layer TFE may be disposed. The thin film encapsulating layer TFE may be disposed on the second electrode EL2. The thin film encapsulating layer TFE may be disposed directly on the second electrode EL2. The thin film encapsulating layer TFE may be a layer or a stacked layer of multiple layers.

The light controlling member CCM-b is disposed on the display panel DP-1. The light controlling member CCM-b may include the light controlling layer CCL, a color filter layer CFL and a base layer BL. For example, the display panel DP-1 may include the organic electroluminescence device OEL emitting first light, and the light controlling member CCM-b may include multiple light controlling parts CCP converting the wavelength of the first light provided from the organic electroluminescence device OEL or transmitting the first light.

The display apparatus DD of an embodiment, shown in FIG. 3C may include the non-luminous area NPXA and luminous areas PXA-R, PXA-G, and PXA-B. Each of the luminous areas PXA-R, PXA-G, and PXA-B may be a region emitting light produced from the organic electroluminescence device OEL. As described in FIG. 3A, the areas of the luminous areas PXA-R, PXA-G, and PXA-B may be different from each other, and the area may mean an area shown on a plane.

In the display apparatus DD of an embodiment, shown in FIG. 3C, the display panel DP-1 is shown to include the organic electroluminescence device OEL including the organic layer OL as a common layer. For example, in the display apparatus DD of an embodiment according to FIG. 3C, the display panel DP-1 may emit light in the same wavelength region irrespective of the luminous areas PXA-R, PXA-G, and PXA-B of the display apparatus DD. For example, the display panel DP-1 may provide the light controlling member CCM-b with blue light which is first color light.

As described in FIG. 3A, in the display apparatus DD of an embodiment, shown in FIG. 3C, at least one among multiple light controlling parts CCP1, CCP2, and CCP3, included in the light controlling layer CCL may be formed from a quantum dot composition QCP of an embodiment.

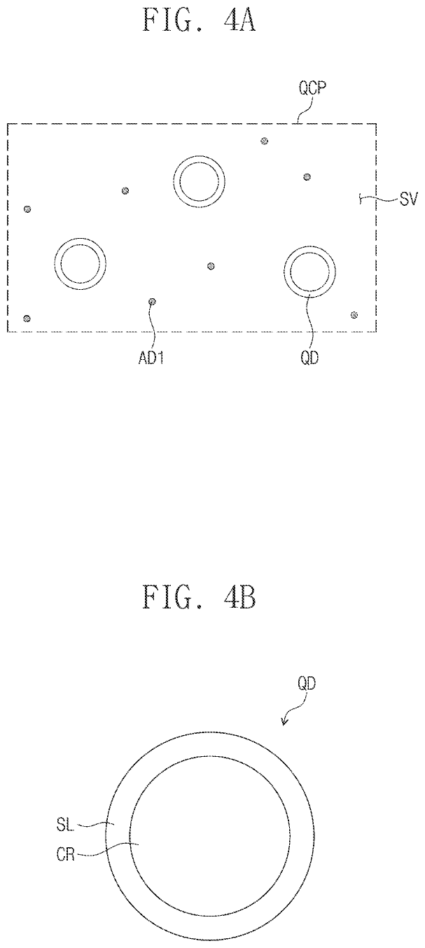

Hereinafter, a quantum dot composition QCP of an embodiment will be explained referring to FIG. 4A and FIG. 4B. FIG. 4A is a schematic diagram showing a part of the quantum dot composition QCP of an embodiment in more detail. FIG. 4B schematically shows a quantum dot QD included in a quantum dot composition QCP according to an embodiment. In the display apparatuses DD of embodiments, described in FIG. 2B, and FIG. 3A to FIG. 3C, at least one among the light controlling parts CCP1, CCP2, and CCP3, included in the light controlling layer CCL may be formed from the quantum dot composition QCP of an embodiment.

The quantum dot QD may have a size of several nm to tens of nm and may have a large surface area, and accordingly, may be chemically unstable, and oxidation and/or deterioration may occur at the surface due to moisture, heat, or light. Accordingly, the quantum dot QD may be oxidized or deteriorated by heat and light produced during the operation of the display apparatus DD to reduce emission efficiency and reliability. The deterioration of the quantum dot QD may occur by light or heat, and among them, the deterioration by light is irreversible phenomenon appearing in the presence of moisture and oxygen and may induce the reliability issues of the display apparatus DD. Photocorrosion may be the deterioration due to a surface degradation of the quantum dot QD and may occur in case that the quantum dot QD are irradiated with light in the presence of moisture and oxygen. The main cause of the photocorrosion of the quantum dot QD includes light, moisture, and oxygen, and among them, the light is an essential factor for accomplishing the display apparatus DD, and the elimination of the light may be impossible. Accordingly, in order to prevent the photocorrosion of the quantum dot QD applied to the display apparatus DD, a method of removing moisture and oxygen may be required. In the disclosure, a first compound AD1 including a first functional group that is a substituent which may react with and remove moisture, is introduced, and moisture penetrating during processing may be removed, while removing moisture present around the quantum dot QD during operation. Accordingly, the deterioration by photocorrosion may be prevented, and the reliability and emission properties of the display apparatus DD may be improved.

The quantum dot composition QCP according to an embodiment of the disclosure may include the first compound AD1 including the first functional group which may react with moisture. The first compound AD1 may include at least one among an acetal group and a ketal group and may play a role of capturing moisture present around the quantum dots QD.

Referring to FIG. 4A and FIG. 4B, the quantum dot composition QCP of an embodiment may include the quantum dots QD and the first compound AD1. As described above, the quantum dot QD may include a core CR and a shell SL wrapping the core CR. However, an embodiment of the disclosure is not limited thereto, and the quantum dot QD may have a structure of a single layer or may have multiple shells SL. On the quantum dots QD included in the quantum dot composition QCP, a same explanation on the quantum dots for the display apparatus DD of an embodiment referring, e.g., to FIG. 3A may be applied.

The quantum dot composition QCP of an embodiment may include the first compound AD1, and the first compound AD1 may include the first functional group. In an embodiment, the first functional group may include at least one among the acetal group and the ketal group.

In the description, the term “substituted or unsubstituted” may correspond to substituted or unsubstituted with one or more substituents selected from a group consisting of a deuterium atom, a halogen atom, a cyano group, a nitro group, an amino group, a silyl group, an oxy group, a hydroxyl group, a thio group, a sulfinyl group, a sulfonyl group, a carbonyl group, a carboxyl group, a boron group, a phoshine oxide group, a phoshine sulfide group, an alkyl group, an alkenyl group, an alkynyl group, a hydrocarbon ring group, an aryl group, and a heterocyclic group, or combinations thereof. Each of the exemplified substituents may be substituted or unsubstituted. For example, a biphenyl group may be interpreted as an aryl group or a phenyl group substituted with a phenyl group.

In the description, the term “forming a ring via the combination with an adjacent group” may mean forming a substituted or unsubstituted hydrocarbon ring, or a substituted or unsubstituted heterocycle via the combination with an adjacent group. The hydrocarbon ring may include an aliphatic hydrocarbon ring and an aromatic hydrocarbon ring. The heterocycle may include an aliphatic heterocycle and an aromatic heterocycle. The hydrocarbon ring and the heterocycle may be monocycles or polycycles. The ring formed via the combination with an adjacent group may be combined with another ring to form a spiro structure.

In the description, the term “adjacent group” may mean a substituent substituted for an atom which is directly combined with an atom substituted with a corresponding substituent, another substituent substituted for an atom which is substituted with a corresponding substituent, or a substituent sterically positioned at the nearest position to a corresponding substituent. For example, in 1,2-dimethylbenzene, two methyl groups may be interpreted as “adjacent groups” to each other, and in 1,1-diethylcyclopentene, two ethyl groups may be interpreted as “adjacent groups” to each other. In 4,5-dimethylphenanthrene, two methyl groups may be interpreted as “adjacent groups” to each other.

In the description, a halogen atom may be a fluorine atom, a chlorine atom, a bromine atom, or an iodine atom.

In the description, the alkyl group may be a linear, branched, or cyclic type. A carbon number of the alkyl group may be 1 to 50, 1 to 30, 1 to 20, 1 to 10, or 1 to 6. Examples of the alkyl group may include methyl, ethyl, n-propyl, isopropyl, n-butyl, s-butyl, t-butyl, i-butyl, 2-ethylbutyl, 3,3-dimethylbutyl, n-pentyl, i-pentyl, neopentyl, t-pentyl, cyclopentyl, 1-methylpentyl, 3-methylpentyl, 2-ethylpentyl, 4-methyl-2-pentyl, n-hexyl, 1-methylhexyl, 2-ethylhexyl, 2-butylhexyl, cyclohexyl, 4-methylcyclohexyl, 4-t-butylcyclohexyl, n-heptyl, 1-methylheptyl, 2,2-dimethylheptyl, 2-ethylheptyl, 2-butylheptyl, n-octyl, t-octyl, 2-ethyloctyl, 2-butyloctyl, 2-hexyloctyl, 3,7-dimethyloctyl, cyclooctyl, n-nonyl, n-decyl, adamantyl, 2-ethyldecyl, 2-butyldecyl, 2-hexyldecyl, 2-octyldecyl, n-undecyl, n-dodecyl, 2-ethyldodecyl, 2-butyldodecyl, 2-hexyldocecyl, 2-octyldodecyl, n-tridecyl, n-tetradecyl, n-pentadecyl, n-hexadecyl, 2-ethylhexadecyl, 2-butylhexadecyl, 2-hexylhexadecyl, 2-octylhexadecyl, n-heptadecyl, n-octadecyl, n-nonadecyl, n-eicosyl, 2-ethyleicosyl, 2-butyleicosyl, 2-hexyleicosyl, 2-octyleicosyl, n-henicosyl, n-docosyl, n-tricosyl, n-tetracosyl, n-pentacosyl, n-hexacosyl, n-heptacosyl, n-octacosyl, n-nonacosyl, or n-triacontyl, etc., without limitation.

In the description, the alkenyl group may mean a hydrocarbon group including one or more carbon double bonds in the middle or at the terminal of an alkyl group having a carbon number of 2 or more. The alkenyl group may be a linear chain or a branched chain. The carbon number is not specifically limited, but may be 2 to 30, 2 to 20, or 2 to 10. Examples of the alkenyl group may include a vinyl group, a 1-butenyl group, a 1-pentenyl group, a 1,3-butadienyl aryl group, a styrenyl group, or a styrylvinyl group, etc., without limitation.

In the description, the alkynyl group may mean a hydrocarbon group including one or more carbon triple bonds in the middle or at the terminal of an alkyl group having a carbon number of 2 or more. The alkynyl group may be a linear chain or a branched chain. The carbon number is not specifically limited, but may be 2 to 30, 2 to 20, or 2 to 10. Examples of the alkynyl group include an ethynyl group, or a propynyl group, etc., without limitation.

In the description, the aryl group may mean an optional functional group or substituent derived from an aromatic hydrocarbon ring. The aryl group may be a monocyclic aryl group or a polycyclic aryl group. The carbon number for forming rings in the aryl group may be 6 to 30, 6 to 20, or 6 to 15. Examples of the aryl group may include phenyl, naphthyl, fluorenyl, anthracenyl, phenanthryl, biphenyl, terphenyl, quaterphenyl, quinquephenyl, sexiphenyl, triphenylenyl, pyrenyl, benzofluoranthenyl, or chrysenyl, etc., without limitation.

In the description, a heteroaryl group may include one or more among B, O, N, P, Si, and S as heteroatoms. If the heteroaryl group includes two or more heteroatoms, two or more heteroatoms may be a same or different. The heteroaryl group may be a monocyclic heterocyclic group or polycyclic heterocyclic group. The carbon number for forming rings of the heteroaryl group may be 2 to 30, 2 to 20, or 2 to 10. Examples of the heteroaryl group may include thiophene, furan, pyrrole, imidazole, pyridine, bipyridine, pyrimidine, triazine, triazole, acridyl, pyridazine, pyrazinyl, quinoline, quinazoline, quinoxaline, phenoxazine, phthalazine, pyrido pyrimidine, pyrido pyrazine, pyrazino pyrazine, isoquinoline, indole, carbazole, N-arylcarbazole, N-heteroarylcarbazole, N-alkylcarbazole, benzoxazole, benzoimidazole, benzothiazole, benzocarbazole, benzothiophene, dibenzothiophene, thienothiophene, benzofuran, phenanthroline, thiazole, isoxazole, oxazole, oxadiazole, thiadiazole, phenothiazine, dibenzosilole, or dibenzofuran, etc., without limitation.

In the description, a same explanation on the above-described aryl group may be applied to an arylene group except that the arylene group is a divalent group. A same explanation on the above-described heteroaryl group may be applied to a heteroarylene group except that the heteroarylene group is a divalent group.

In the description, the carbon number of the carboxyl group is not specifically limited, but the carbon number may be 1 to 40, 1 to 30, or 1 to 20. For example, the carboxyl group may have the structures below, but is not limited thereto.

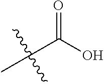 [SMILES: *C(=O)O]

In the description, the thio group may include an alkyl thio group and an aryl thio group. The thio group may mean the above-defined alkyl group or aryl group combined with a sulfur atom. Examples of the thio group may include a methylthio group, an ethylthio group, a propylthio group, a pentylthio group, a hexylthio group, an octylthio group, a dodecylthio group, a cyclopentylthio group, a cyclohexylthio group, a phenylthio group, or a naphthylthio group, etc., without limitation.

In the description, the oxy group may mean the above-defined alkyl group or aryl group which is combined with an oxygen atom. The oxy group may include an alkoxy group and an aryl oxy group. The alkoxy group may be a linear, a branched, or a cyclic chain. The carbon number of the alkoxy group is not specifically limited but may be, for example, 1 to 20 or 1 to 10. Examples of the oxy group may include methoxy, ethoxy, n-propoxy, isopropoxy, butoxy, pentyloxy, hexyloxy, octyloxy, nonyloxy, decyloxy, or benzyloxy, etc. However, an embodiment of the disclosure is not limited thereto.

In the description, the carbon number of an amine group is not specifically limited, but may be 1 to 30. The amine group may include an alkyl amine group and an aryl amine group. Examples of the amine group may include a methylamine group, a dimethylamine group, a phenylamine group, a diphenylamine group, a naphthylamine group, a 9-methyl-anthracenylamine group, or a tripenylamine group, etc., without limitation.

In the description, a direct linkage may mean a single bond.

In the description, “ [symbol] ” may mean a position to be connected.

In the description, (meth)acrylate may mean acrylate and methacrylate.

In the description, monofunctional (meth)acrylate may mean (meth)acrylate having one functional group. The monofunctional (meth)acrylate may mean (meth)acrylate including one (meth)acryloyl group in one molecule. In the resin composition of an embodiment, the monofunctional (meth)acrylate may include multiple different (meth)acrylates. For example, in the resin composition of an embodiment, the monofunctional (meth)acrylate may include at least one monofunctional acrylate and at least one monofunctional methacrylate.

In the description, a bifunctional (meth)acrylate monomer may mean a (meth)acrylate monomer having two functional groups. The bifunctional (meth)acrylate monomer may mean a (meth)acrylate monomer including two (meth)acryloyl groups in one molecule. In the resin composition of an embodiment, the bifunctional (meth)acrylate monomer may include multiple different monomers. For example, in the resin composition of an embodiment, the bifunctional (meth)acrylate monomer may include at least one bifunctional acrylate monomer and at least one bifunctional methacrylate monomer.

In an embodiment, the first compound AD1 may be represented by Formula 1 below.

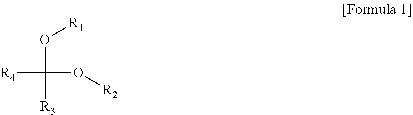

In Formula 1, R₁ and R₂ may be each independently a substituted or unsubstituted alkyl group of 1 to 20 carbon atoms. In an embodiment, R₁ and R₂ may be combined with each other to form a ring. In an embodiment, the substituents represented by R₁ and R₂ may be substituted or unsubstituted alkyl groups of 1 to 4 carbon atoms in view of an easiness of a hydrolysis of the first compound AD1. For example, R₁ and R₂ may be each independently a substituted or unsubstituted methyl group, a substituted or unsubstituted ethyl group, a substituted or unsubstituted n-propyl group, a substituted or unsubstituted i-propyl group, a substituted or unsubstituted n-butyl group, a substituted or unsubstituted s-butyl group, a substituted or unsubstituted t-butyl group, or a substituted or unsubstituted i-butyl group. R₁ and R₂ may be each independently a substituted or unsubstituted methyl group, or a substituted or unsubstituted ethyl group. If R₁ and R₂ of Formula 1 are each independently a substituted or unsubstituted alkyl group of 1 to 4 carbon atoms, the hydrolysis reaction of the first compound AD1 may become easier, and moisture capturing rate by the hydrolysis of the first compound AD1 may increase further, and accordingly, the reliability and emission properties of the display apparatus DD may be improved further.

In Formula 1, R₃ and R₄ may be each independently a hydrogen atom, a deuterium atom, a halogen atom, a substituted or unsubstituted alkyl group of 1 to 20 carbon atoms, a substituted or unsubstituted alkenyl group of 2 to 20 carbon atoms, a substituted or unsubstituted alkynyl group of 2 to 20 carbona toms, a substituted or unsubstituted aryl group of 6 to 30 ring-forming carbon atoms, or a substituted or unsubstituted heteroaryl group of 2 to 30 ring-forming carbon atoms.

In an embodiment, the first compound AD1 may be represented by any one among Formula 1-1 to Formula 1-3 below.

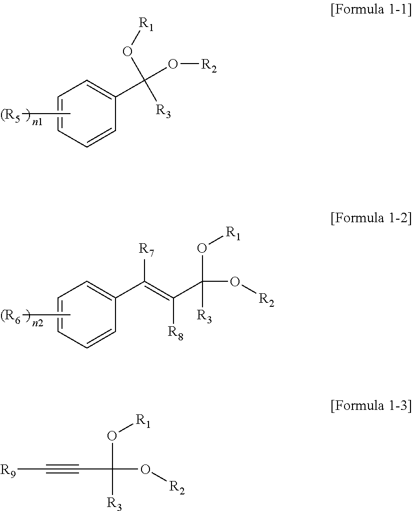

In Formula 1-1 to Formula 1-3, R₅ and R₆ may be each independently a hydrogen atom, a deuterium atom, a halogen atom, a substituted or unsubstituted carboxyl group, a substituted or unsubstituted thio group, a substituted or unsubstituted amine group, a substituted or unsubstituted phosphine group, a substituted or unsubstituted hydroxyl group, a substituted or unsubstituted oxy group, a substituted or unsubstituted nitro group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms. In an embodiment, R₅ and R₆ may be combined with an adjacent group to form a ring.

In Formula 1-1 to Formula 1-3, R₇ to R₉ may be each independently a hydrogen atom, a deuterium atom, a halogen atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In Formula 1-1 to Formula 1-3, n1 and n2 may be each independently an integer of 0 to 5. In case that each of n1 and n2 is 0, the first compound of an embodiment may be unsubstituted with R₅ and R₆. Cases where each of n1 and n2 is 5, and each of R₅ and R₆ is a hydrogen atom, may be substantially identical or similar to cases where each of n1 and n2 is 0. In case that each of n1 and n2 is an integer of 2 or more, each of multiple R₅ and R₆ may be equal to each other, or at least one among multiple R₅ and R₆ may be different.

In Formula 1-1 to Formula 1-3, the same contents explained in Formula 1 may be applied for R₁ to R₃.

In an embodiment, the first compound AD1 may further include a second functional group which is bonded to a surface of the quantum dot QD. The second functional group may be different from the first functional group. In an embodiment, the second functional group may include at least one among a carboxyl group, a thio group, an amine group, a phosphine group, and a hydroxyl group. Though not shown, the second functional group of the first compound AD1 may be provided in a bonded state with the quantum dot QD in the quantum dot composition QCP. However, an embodiment of the disclosure is not limited thereto, and the second functional group of the first compound AD1 may be provided in an unbonded state with the quantum dot QD in the quantum dot composition QCP and may react with the surface of the quantum dot QD during subsequent processes to form a bond.

In an embodiment, the first compound AD1 may be represented by any one among Formula 2-1 to Formula 2-5 below.

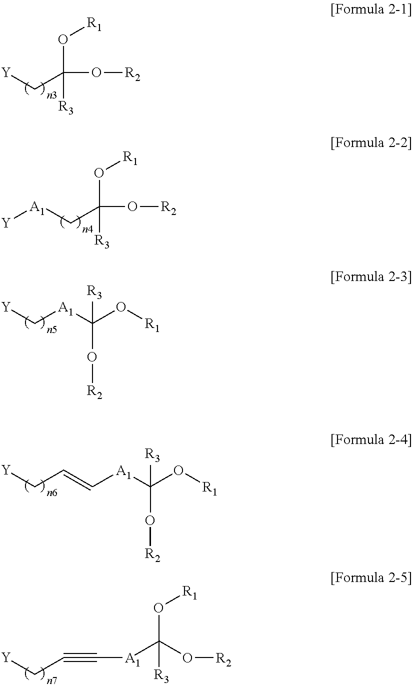

In Formula 2-1 to Formula 2-5, Y may be a substituted or unsubstituted carboxyl group, a substituted or unsubstituted thio group, a substituted or unsubstituted amine group, a substituted or unsubstituted phosphine group, or a substituted or unsubstituted hydroxyl group. Y may be the above-described second functional group moiety.

In Formula 2-2 to Formula 2-5, A₁ may be a substituted or unsubstituted arylene group of 6 to 30 ring-forming carbon atoms, or a substituted or unsubstituted heteroarylene group of 2 to 30 ring-forming carbon atoms.

In Formula 2-2 to Formula 2-5, n3 to n7 are each independently an integer of 0 to 20.

In Formula 2-1 to Formula 2-5, the same contents explained in Formula 1 may be applied for R₁ to R₃.

In an embodiment, the first compound may further include a third functional group. The first compound AD1 may include the first functional group and a third functional group which is different from the first functional group. The third functional group may include a (meth)acrylate group. In an embodiment, the first compound AD1 may include at least one or more of the third functional groups in a molecule.

If the first compound AD1 further includes the third functional group, the first compound AD1 of an embodiment may be a photocurable compound. The first compound AD1 including the first functional group and the third functional group may be included in the quantum dot composition QCP to form a polymer product without adversely influencing the dispersion of the quantum dots QD.

The quantum dot composition QCP of an embodiment may further include another photocurable compound (in addition to the first compound AD1). The quantum dot composition QCP of an embodiment may further include a photocurable compound which is different from the first compound AD1 and includes a carbon-carbon unsaturated bond. The photocurable compound including the carbon-carbon unsaturated bond is not specifically limited as long as it includes a carbon-carbon unsaturated bond and is photopolymerizable, but may use, for example, monofunctional or polyfunctional (meth)acrylate.

The quantum dot composition QCP of an embodiment may further include a polymer binder. For example, the quantum dot composition QCP may include at least one among an acryl-based resin, a methacryl-based resin, polyisoprene, a vinyl-based resin, an epoxy-based resin, a urethane-based resin, a cellulose-based resin, a siloxane-based resin, a polyimide-based resin, a polyamide-based resin, and a perylene-based resin. However, an embodiment of the disclosure is not limited thereto.

The monofunctional (meth)acrylate may include, for example, phenoxyethyl (meth)acrylate, phenoxyethoxyethyl (meth)acrylate, phenoxyhydroxypropyl (meth)acrylate, phenylphenoxyethyl (meth)acrylate, bromophenoxyethyl (meth)acrylate, polyoxy ethylene nonylphenyl ether (meth)acrylate, isobornyl (meth)acrylate, adamantyl (meth)acrylate, methyladamantyl (meth)acrylate, ethyladamantyl (meth)acrylate, bornyl (meth)acrylate, tricyclodecanyl (meth)acrylate, dicyclopentanyl (meth)acrylate, dicyclopentenyl (meth)acrylate, cyclohexyl (meth)acrylate, butylcyclohexyl (meth)acrylate, methyl (meth)acrylate, ethyl (meth)acrylate, propyl (meth)acrylate, isopropyl (meth)acrylate, butyl (meth)acrylate, amyl (meth)acrylate, isobutyl (meth)acrylate, t-butyl (meth)acrylate, pentyl (meth)acrylate, hexyl (meth)acrylate, heptyl (meth)acrylate, octyl (meth)acrylate, isooctyl (meth)acrylate, ethylhexyl (meth)acrylate, nonyl (meth)acrylate, decyl (meth)acrylate, isodecyl (meth)acrylate, undecyl (meth)acrylate, dodecyl (meth)acrylate, lauryl (meth)acrylate, stearyl (meth)acrylate, isostearyl (meth)acrylate, benzyl (meth)acrylate, ethoxy di ethylene glycol (meth)acrylate, polyethylene glycol mono(meth)acrylate, polypropylene glycol mono(meth)acrylate, methoxyethylene glycol (meth)acrylate, ethoxyethyl (meth)acrylate, or mixtures thereof. However, an embodiment of the disclosure is not limited thereto.

The polyfunctional (meth)acrylate may include, for example, ethylene glycol di(meth)acrylate, triethylene glycol di(meth)acrylate, diethylene glycol di(meth)acrylate, 1,4-butanediol di(meth)acrylate, 1,6-hexanediol di(meth)acrylate, neopentyl glycol di(meth)acrylate, pentaerythritol di(meth)acrylate, pentaerythritol tri(meth)acrylate, pentaerythritol tetra(meth)acrylate, dipentaerythritol di(meth)acrylate, dipentaerythritol tri(meth)acrylate, dipentaerythritol penta(meth)acrylate, pentaerythritol hexa(meth)acrylate, bisphenol A epoxyacrylate, bisphenyl A di(meth)acrylate, trimethylolpropane tri(meth)acrylate, novolak epoxy (meth)acrylate, ethylene glycol monomethyl ether (meth)acrylate, tris(meth)acryloyloxyethyl phosphate, diethylene glycol di(meth)acrylate, triethylene glycol di(meth)acrylate, propylene glycol di(meth)acrylate, or mixtures thereof. However, an embodiment of the disclosure is not limited thereto.

The quantum dot composition QCP of an embodiment may further include an additional additive as necessary. The additive may be suitably selected from common additives well-known in this technical field for controlling physical properties required for the quantum dot composition QCP. For example, a light stabilizer, a crosslinking agent, an antioxidant, a chain transfer agent, a photosensitizer, a polymerization inhibitor, a leveling agent, a surfactant, an adhesion imparting agent, a plasticizer, an ultraviolet absorbent, a storage stabilizer, an antistatic agent, an inorganic filler, a pigment, a dye, or the like may be used, without limitation. The additive may be used solely or as a mixture of two or more.

In the quantum dot composition QCP of an embodiment, if the first compound AD1 includes the first functional group and the third functional group, the first compound AD1 may form a medium in which quantum dots QD are dispersed in a light controlling part CCP after photocuring and may play a role of protecting the quantum dots QD from moisture and/or oxygen, thereby further improving the emission efficiency and reliability of a display apparatus DD.

In an embodiment, if the first compound includes the first functional group and the third functional group, the first compound may be represented by any one among Formula 3-1 to Formula 3-3 below.

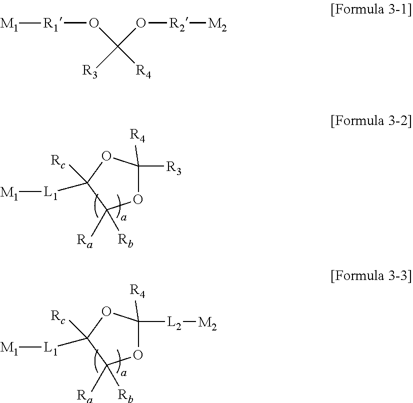

In Formula 3-1, R₁′ and R₂′ may be each independently a substituted or unsubstituted divalent alkyl group of 1 to 20 carbon atoms.

In Formula 3-1 to Formula 3-3, M₁ and M₂ may be each independently a (meth)acrylate group. For example, M₁ and M₂ may be each independently represented by Formula 3a below.

In Formula 3-2 and Formula 3-3, L₁ and L₂ may be each independently a direct linkage, or a substituted or unsubstituted divalent alkyl group of 1 to 20 carbon atoms.

In Formula 3-1 to Formula 3-3, Rₐ to R_{c} may be each independently a hydrogen atom, or a substituted or unsubstituted alkyl group of 1 to 20 carbon atoms.

In Formula 3-2 and Formula 3-3, “a” may be 1 or 2.

In Formula 3-1 to Formula 3-3, the same contents explained in Formula 1 may be applied for R₃ and R₄.

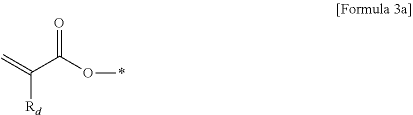

In Formula 3a, R_{d} may be a hydrogen atom, or a substituted or unsubstituted methyl group.

The quantum dot composition QCP of an embodiment may include two or more types of the first compound AD1. If the quantum dot composition QCP includes two or more types of the first compound AD1, the first compound AD1 may include a first compound AD1 including the first functional group and a first compound AD1 including both the first functional group and the third functional group. However, an embodiment of the disclosure is not limited thereto.

If the quantum dot composition QCP of an embodiment includes the first compound AD1 including the first functional group and the third functional group, the quantum dot composition QCP may further include at least one photoinitiator. If the quantum dot composition QCP includes multiple photoinitiators, different photoinitiators may be activated by ultraviolet light having different central wavelengths.

The photoinitiator may be at least one selected among 2,2-dimethoxy-1,2-diphenylethan-1-one, 1-hydroxy-cyclohexyl-phenyl-ketone, 2-hydroxy-2-methyl-1-phenyl-1-propanone, 2-hydroxy-1-[4-(2-hydroxyethoxy)phenyl]-2-methyl-1-propanone, and 2-hydroxy-1-{4-[4-(2-hydroxy-2-methyl-propionyl)-benzyl]-phenyl}-2-methylpropan-1-one.

The photoinitiator may be at least one among 2-methyl-1[4-(methylthio)phenyl]-2-morpholinopropan-1-one, 2-benzyl-2-dimethylamino-1-(4-morpholinophenyl)-butanone-1,2-dimethylamino-2-(4-methyl-benzyl)-1-(4-morpholin-4-yl-phenyl)-butan-1-one, 2,4,6-trimethylbenzoyl-diphenylphosphine oxide, 2,4,6-trimethylbenzoyl-diphenyl phosphinate, bis(2,4,6-trimethylbenzoyl)-phenylphosphineoxide, [1-(4-phenylsulfanylbenzoyl)heptylideneamino]benzoate, [1-[9-ethyl-6-(2-methylbenzoyl)carbazol-3-yl]ethylideneamino] acetate, and bis(2,4-cyclopentadienyl)bis[2,6-difluoro-3-(1-pyrryl)phenyl] titanium(IV).

In an embodiment, the first compound AD1 may be at least one among the compounds represented in Compound Group 1 to Compound Group 3 below. At least one among multiple light controlling parts CCP1, CCP2, and CCP3 of an embodiment may include at least one compound among the compounds represented in Compound Group 1 to Compound Group 3 below.

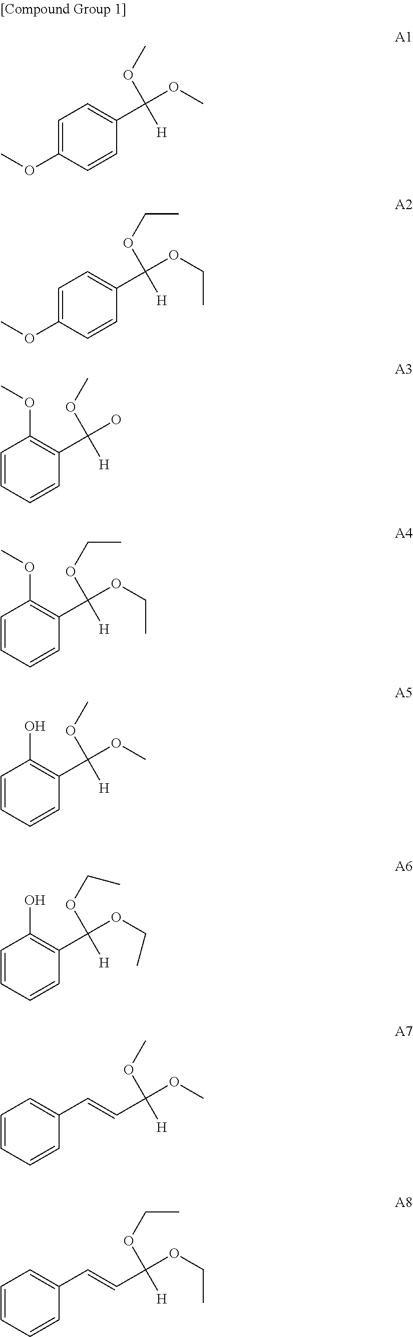

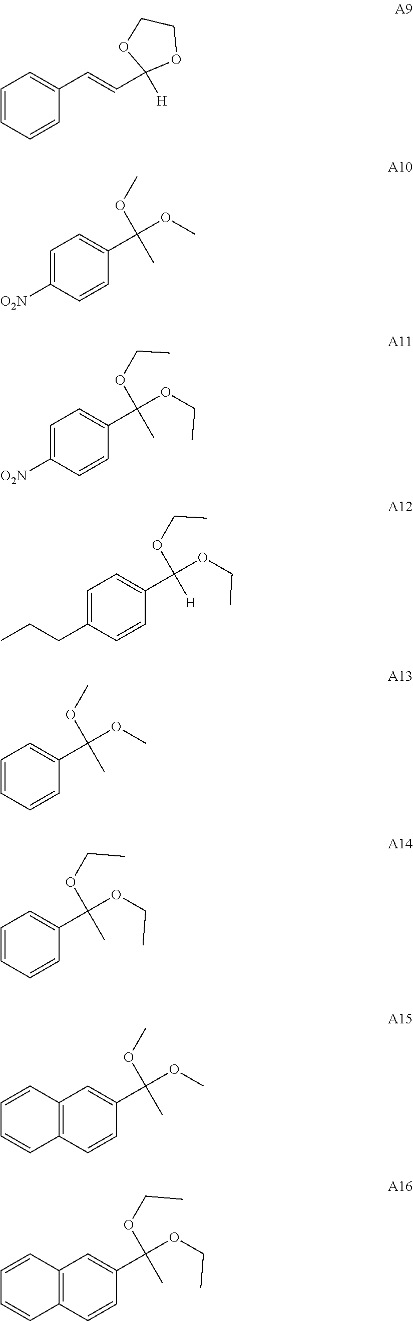

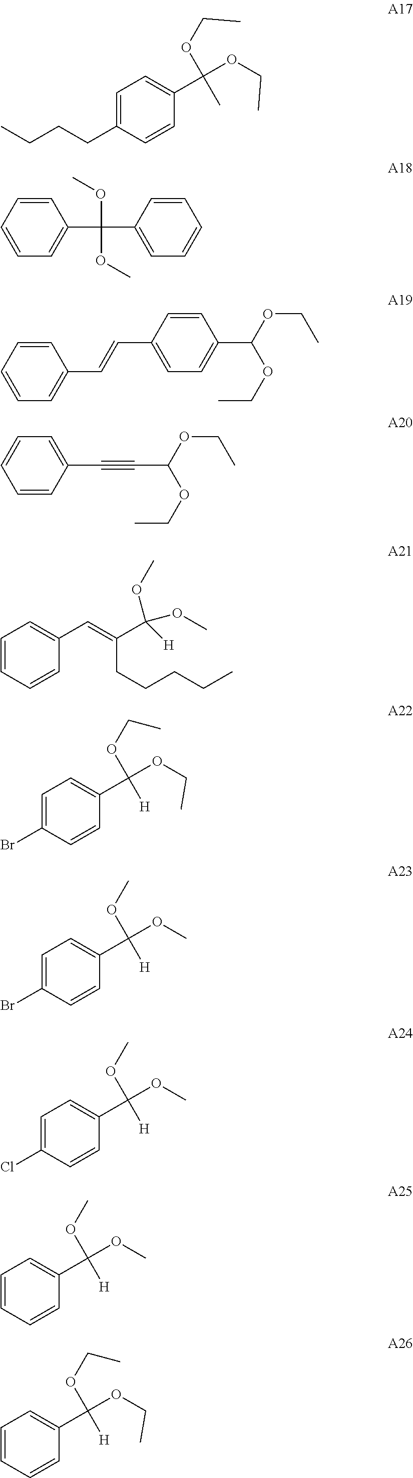

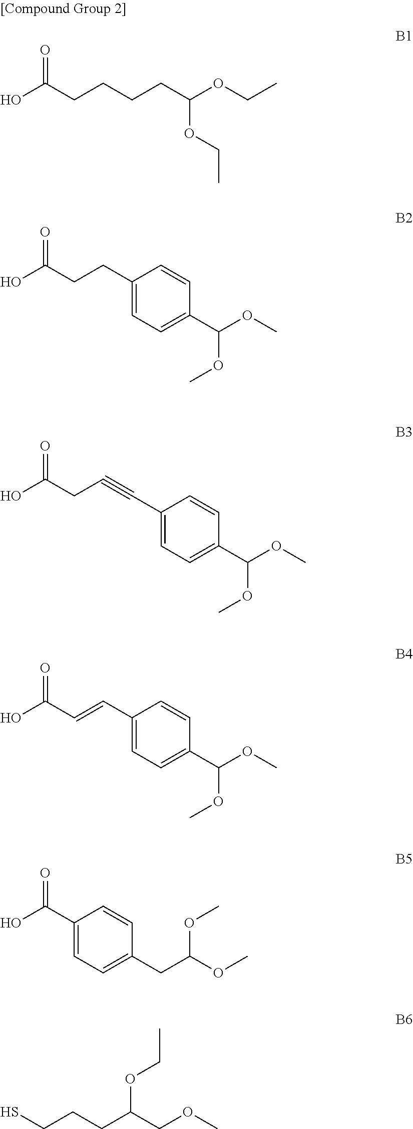 [SMILES: CCOC(CCCCC(=O)O)OCC ; COC(OC)c1ccc(CCC(=O)O)cc1 ; COC(OC)c1ccc(C#CCC(=O)O)cc1 ; COC(OC)c1ccc(/C=C/C(=O)O)cc1 ; COC(Cc1ccc(C(=O)O)cc1)OC ; CCOC(CCCS)COC]

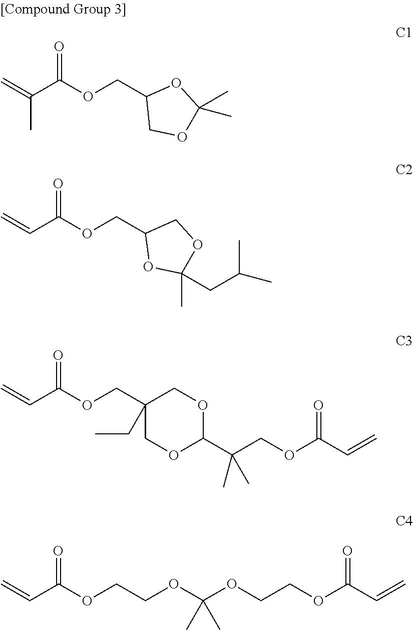

Referring to FIG. 4A again, the quantum dot composition QCP may include a solvent SV in which the quantum dots QD and the first compound AD1 are dispersed. The quantum dots QD and the first compound AD1 may be dispersed in the solvent SV and provided. In a formation step of a light controlling part CCP, the solvent SV may be removed. However, an embodiment of the disclosure is not limited thereto, and a portion of the solvent SV may remain in the light controlling part CCP.

The solvent SV may be an organic solvent or an inorganic solvent such as water. The organic solvent may include, for example, hexane, toluene, chloroform, dimethyl sulfoxide, octane, xylene, hexadecane, cyclohexylbenzene, triethylene glycol monobutyl ether), dimethyl formamide, decane, dodecane hexadecene, cyclohexylbenzene, tetrahydronaphthalene, ethylnaphthalene, ethylbiphenyl, isopropylnaphthalene, dii sopropylnaphthalene, diisopropylbiphenyl, xylene, isopropylbenzene, pentylbenzene, diisopropylbenzene, decahydronaphthalene, phenylnaphthalene, cyclohexyldecahydronaphthalene, decylbenzene, dodecylbenzene, octylbenzene, cyclohexane, cyclopentane, cycloheptane, methanol, ethanol, propanol, isopropanol, ethylene glycol, propylene glycol, diethylene glycol, or the like, without limitation.

In an embodiment, the amount of the first compound AD1 may be about 30 wt % or less based on about 100 wt % of the total amount of the quantum dot composition QCP. For example, the amount of the first compound AD1 may be about 0.01 wt % to about 30 wt %. If the amount of the first compound AD1 included in the quantum dot composition QCP satisfies the aforementioned range, sufficient moisture capturing effects may be obtained without adversely influencing the dispersion of the quantum dots QD in the whole composition, and the emission efficiency properties and reliability of the display apparatus DD may be improved. If the amount of the first compound AD1 is greater than about 30 wt %, the dispersing properties of the quantum dots QD may be degraded, and the function of other components included in the quantum dot composition QCP may be degraded.

FIG. 5 is a schematic cross-sectional view showing a part of a light controlling member CCM according to an embodiment of the disclosure. FIG. 5 shows a schematic enlarged diagram on area AA of FIG. 3A. Hereinafter, the diagram is centered on the structure of a first light controlling part CCP1 among multiple light controlling parts CCP1, CCP2, and CCP3, but a same explanation on the first light controlling part CCP1 may be applied to at least one among the second light controlling part CCP2 and the third light controlling part CCP3.

Referring to FIG. 3A and FIG. 5 together, in the light controlling member CCM according to an embodiment, at least one among the multiple light controlling parts CCP may include a quantum dot QD and an additive AD. The additive AD may include a first functional group or a group formed by the hydrolysis of the first functional group. The additive AD may include a first compound AD1 including the first functional group or a second compound AD2 including a group formed by the hydrolysis of the first functional group. The second compound AD2 may mean a material formed by the hydrolysis of the first compound AD1. In an embodiment, the first functional group may include at least one among an acetal group and a ketal group. The group formed by the hydrolysis of the first functional group may be a ketone group or an aldehyde group.

In an embodiment, the first compound AD1 may be represented by Formula 1 below, and the second compound AD2 may be represented by Formula 1A below.

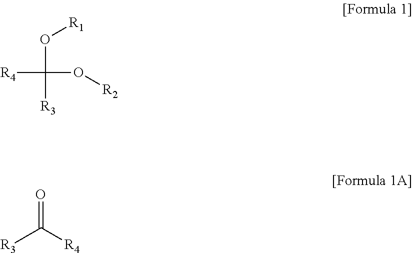

In Formula 1, R₁ and R₂ may be each independently a substituted or unsubstituted alkyl group of 1 to 20 carbon atoms. In an embodiment, R₁ and R₂ may be combined with each other to form a ring. In an embodiment, R₁ and R₂ may be each independently a substituted or unsubstituted alkyl group of 1 to 10 carbon atoms. For example, R₁ and R₂ may be each independently a substituted or unsubstituted methyl group, or a substituted or unsubstituted ethyl group.

In Formula 1 and Formula 1A, R₃ and R₄ may be each independently a hydrogen atom, a deuterium atom, a halogen atom, a substituted or unsubstituted alkyl group of 1 to 20 carbon atoms, a substituted or unsubstituted alkenyl group of 2 to 20 carbon atoms, a substituted or unsubstituted alkynyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms.

The additive AD may be represented by any one among Formula 1-1 to Formula 1-6 below. In an embodiment, the first compound AD1 may be represented by any one among Formula 1-1 to Formula 1-3 below, and the second compound AD2 may be represented by any one among Formula 1-4 to Formula 1-6 below.

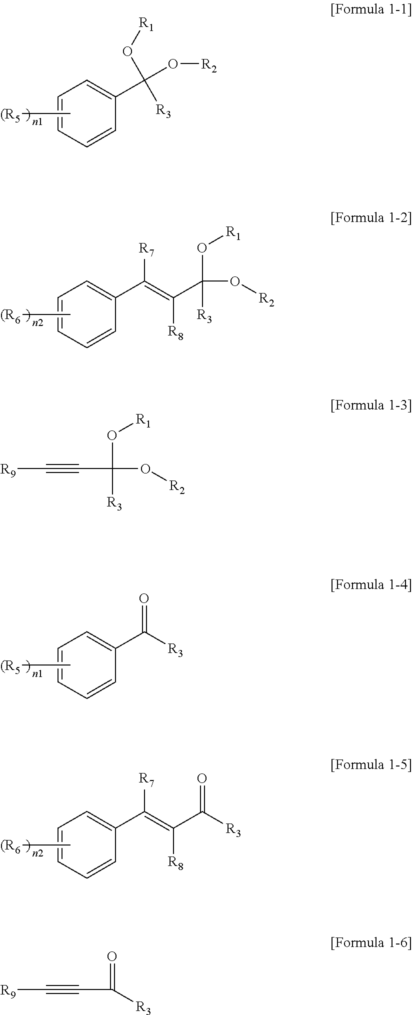

In Formula 1-1 to Formula 1-6, R₅ and R₆ may be each independently a hydrogen atom, a deuterium atom, a halogen atom, a substituted or unsubstituted carboxyl group, a substituted or unsubstituted thio group, a substituted or unsubstituted amine group, a substituted or unsubstituted phosphine group, a substituted or unsubstituted hydroxyl group, a substituted or unsubstituted oxy group, a substituted or unsubstituted nitro group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms. In an embodiment, each of R₅ and R₆ may be combined with an adjacent group to form a ring.

In Formula 1-1 to Formula 1-6, R₇ to R₉ may be each independently a hydrogen atom, a deuterium atom, a halogen atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. R₇ and R₈ may be each independently a hydrogen atom, or a substituted or unsubstituted alkyl group of 1 to 10 carbon atoms. R₉ may be a substituted or unsubstituted aryl group of 6 to 30 ring-forming carbon atoms. For example, R₉ may be a substituted or unsubstituted phenyl group.

In Formula 1-1 to Formula 1-6, n1 and n2 may be each independently an integer of 0 to 5. In case that each of n1 and n2 is 0, the first compound of an embodiment may be unsubstituted with R₅ and R₆. Cases where each of n1 and n2 is 5, and each of R₅ and R₆ is a hydrogen atom, may be substantially identical or similar to cases where each of n1 and n2 is 0. In case that each of n1 and n2 is an integer of 2 or more, multiple R₅ and R₆ may be equal to each other, or at least one among multiple R₅ and R₆ may be different.

In Formula 1-1 to Formula 1-6, the same contents explained in Formula 1 may be applied for R₁ to R₃.

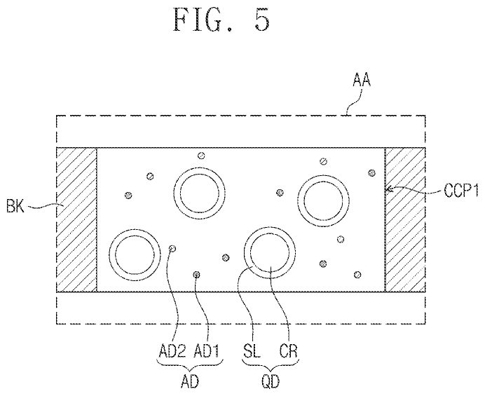

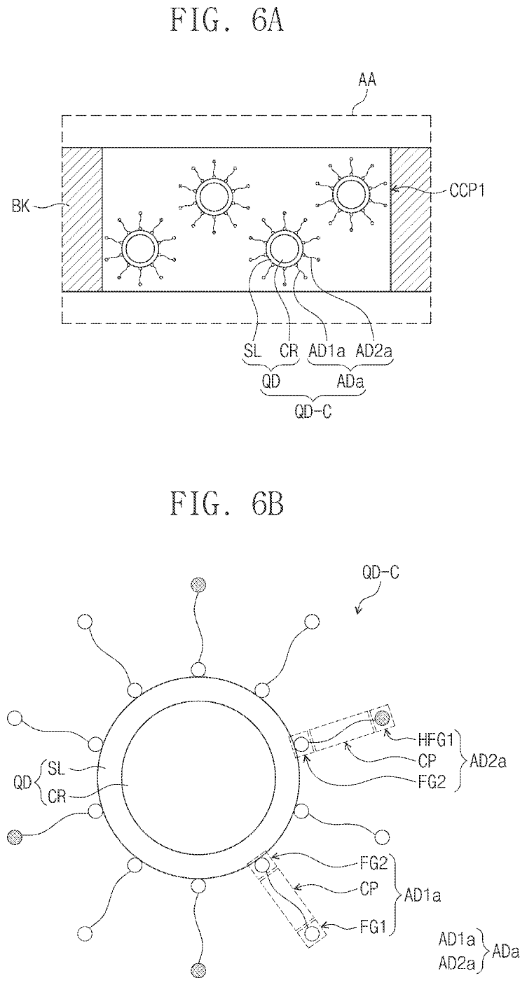

FIG. 6A is a schematic cross-sectional view showing a part of a light controlling member CCM according to an embodiment of the disclosure. FIG. 6B schematically shows a quantum dot QD and an additive ADa, included in the light controlling member CCM according to an embodiment of the disclosure. For the convenience of explanation, FIG. 6B shows a schematic structure of a quantum dot composite QD-C including the quantum dot QD and the additive ADa of bonded to a surface of the quantum dot QD. FIG. 6A is a schematic enlarged diagram of area AA of FIG. 3.

Referring to FIG. 3A, FIG. 6A, and FIG. 6B, at least one among multiple light controlling parts CCP1, CCP2, and CCP3 included in a light controlling layer CCL according to an embodiment may include quantum dot composites QD-C. The quantum dot composite QD-C included in at least one among the light controlling parts CCP1, CCP2, and CCP3 may be the quantum dot QD combined with the additive ADa at the surface thereof. The quantum dot composite QD-C may be the quantum dot QD combined with the additive ADa at the surface thereof for improving a dispersibility and charge injection properties of the quantum dot QD and preventing oxidation and/or corrosion of the quantum dot QD.

In an embodiment, the additive ADa may further include a second functional group FG2 bonded to the surface of the quantum dot QD. The additive ADa may include a first functional group FG1 and a second functional group FG2 or may include a group HFG1 formed by the hydrolysis of the first functional group FG1 and the second functional group FG2. The additive ADa may include a first compound AD1a including the first functional group FG1 and the second functional group FG2, or the additive ADa may include a second compound AD2a including the group HFG1 obtained by the hydrolysis of the first functional group FG1 and the second functional group FG2. The second compound AD2a may be a material formed by the hydrolysis of the first compound AD1a. The same contents of the first functional group of the first compound AD1 in FIG. 4A, or the like, may be applied for the first functional group FG1. The second functional group FG2 may be at least one without specific limitation as long as it is a substituent being combined with the quantum dot QD, for example, at least one among a carboxyl group, a thio group, an amine group, a phosphine group, and a hydroxyl group. Since the additive ADa includes the first functional group FG1 and the second functional group FG2, the additive ADa may play a role of improving the surface modification properties of the quantum dot QD and preventing the oxidation and/or corrosion of the quantum dot QD.

The additive ADa may further include a connecting part CP. The connecting part CP of the additive ADa may connect the first functional group FG1 and the second functional group FG2 or may connect the group HFG1 formed by the hydrolysis of the first functional group FG1 and the second functional group FG2. The connecting part CP may control the length of the additive ADa to play a role of controlling a degree of dispersion of the quantum dot composites QD-C in the quantum dot composition QCP. The connecting part CP may include, for example, at least one among a substituted or unsubstituted alkyl group of 1 to 20 carbon atoms, a substituted or unsubstituted alkenyl group of 2 to 20 carbon atoms, a substituted or unsubstituted alkynyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms. The functional group included or a length of a chain of the connecting part CP may change according to the type of the solvent for dispersing the quantum dot composites QD-C. However, an embodiment of the disclosure is not limited thereto, and the connecting part CP may be omitted from the additive ADa, and the first functional group FG1 and the second functional group FG2 in the additive ADa may be directly linked, and the group HFG1 formed by the hydrolysis of the first functional group FG1 and the second functional group FG2 may be directly linked.

In an embodiment, the additive ADa may be represented by Formula A or Formula B below. The first compound AD1a of the additive ADa of an embodiment may be represented by Formula A below, and the second compound AD2a of the additive ADa of an embodiment may be represented by Formula B below.

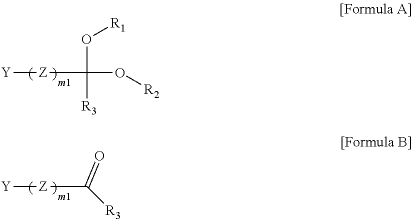

In Formula A and Formula B, Y may be a second functional group FG2. For example, Y may be a substituted or unsubstituted carboxyl group, a substituted or unsubstituted thio group, a substituted or unsubstituted amine group, a substituted or unsubstituted phosphine group, or a substituted or unsubstituted hydroxyl group.

In Formula A and Formula B, Z may be a connecting part CP connecting a first functional group FG1 and a second functional group FG2. Z may be a direct linkage, a substituted or unsubstituted divalent alkyl group of 1 to 20 carbon atoms, a substituted or unsubstituted divalent alkenyl group of 2 to 20 carbon atoms, a substituted or unsubstituted divalent alkynyl group of 2 to 20 carbon atoms, a substituted or unsubstituted arylene group of 6 to 30 carbon atoms, or a substituted or unsubstituted heteroarylene group of 2 to 30 carbon atoms.

In Formula A and Formula B, m1 is an integer of 0 to 20. If m1 is 0, a connection position represented by Z may be a direct linkage. For example, if m1 is 0, the first compound AD1 may not include a connecting part CP connecting the first functional group FG1 and the second functional group FG2.

In Formula A and Formula B, the same contents explained in Formula 1 may be applied for R₁ to R₃.

In an embodiment, the additive ADa may be represented by any one among Formula 2-1 to Formula 2-10 below. The first compound AD1a of the additive ADa may be represented by any one among Formula 2-1 to Formula 2-5 below. The second compound AD2a of the additive ADa may be represented by any one among Formula 2-6 to Formula 2-10 below.

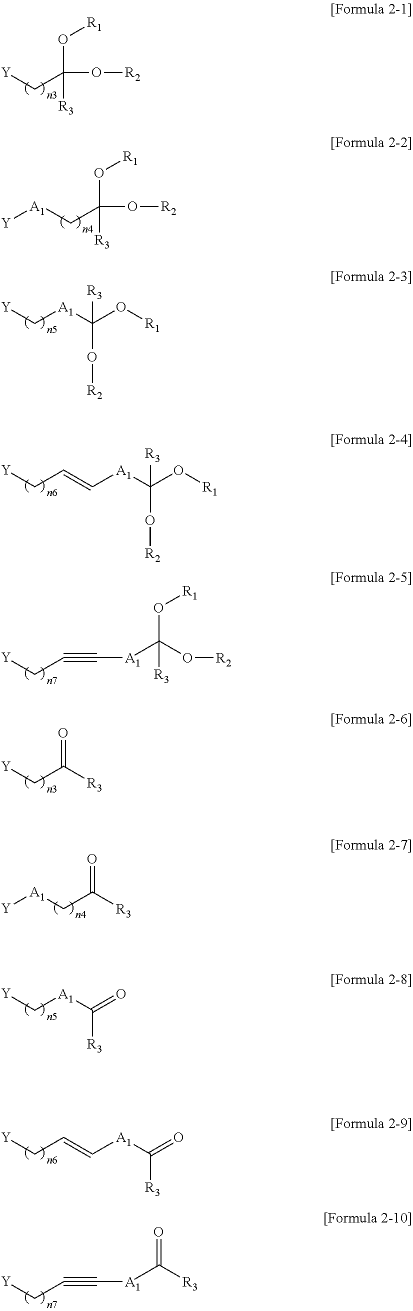

Formula 2-1 to Formula 2-5 may be cases where a type and number of a substituent represented by Z in Formula A are specified, and Formula 2-6 to Formula 2-10 may be cases where a type and number of a substituent represented by Z in Formula B are specified.

In Formula 2-1 to Formula 2-10, Y may be a substituted or unsubstituted carboxyl group, a substituted or unsubstituted thio group, a substituted or unsubstituted amine group, a substituted or unsubstituted phosphine group, or a substituted or unsubstituted hydroxyl group. For example, Y may be an unsubstituted carboxyl group, an unsubstituted thio group, an unsubstituted amine group, an unsubstituted phosphine group, or an unsubstituted hydroxyl group.

In Formula 2-1 to Formula 2-10, A₁ may be a substituted or unsubstituted arylene group of 6 to 30 ring-forming carbon atoms, or a substituted or unsubstituted heteroarylene group of 2 to 30 ring-forming carbon atoms. In an embodiment, A₁ may be a substituted or unsubstituted arylene group of 6 to 30 ring-forming carbon atoms. For example, A₁ may be a substituted or unsubstituted phenylene.

In Formula 2-1 to Formula 2-10, n3 to n7 may be each independently an integer of 0 to 20.

In Formula 2-1 to Formula 2-10, the same contents explained in Formula 1 may be applied for R₁ to R₃.

Referring to FIG. 3A and FIG. 6A, at least one among the multiple light controlling parts CCP1, CCP2, and CCP3 in the light controlling layer CCL of an embodiment may be formed from the quantum dot composition QCP of an embodiment.

At least one among the multiple light controlling parts CCP1, CCP2, and CCP3 may include multiple quantum dot composites QD-C. In an embodiment, among the multiple light controlling parts CCP1, CCP2, and CCP3, the first light controlling part CCP1 and the second light controlling part CCP2 may be formed from the quantum dot composition QCP of an embodiment, and the first light controlling part CCP1 and the second light controlling part CCP2 may include multiple quantum dot composites QD-C. If at least one among the light controlling parts CCP1, CCP2, and CCP3 includes multiple quantum dot composites QD-C, the quantum dot composites QD-C included in the at least one light controlling part CCP may be stacked to form a layer. In FIG. 6A, the quantum dot composites QD-C of which cross-sections form circles are arranged into roughly two layers as an embodiment, but an embodiment of the disclosure is not limited thereto. For example, according to a thickness of the at least one light controlling part CCP, a shape of the quantum dots QD included in the at least one light controlling part CCP, an average diameter of the quantum dots QD, a type of the additive ADa connected with the quantum dot QD, or the like, an arrangement of the quantum dot composites QD-C may be changed. The quantum dot composites QD-C in the at least one light controlling part CCP may be arranged to be next to form a layer or multiple layers of two layers, three layers, or the like.

The second functional group FG2 of the additive ADa may be bonded to the surface of the quantum dot QD, and the first functional group FG1 may be exposed to an outside of the quantum dot QD. As shown in FIG. 6B, according to the bonding of the second functional group FG2 to the surface of the quantum dot QD, the first functional group FG1 which plays a role of preventing the oxidation and/or corrosion of the quantum dot QD may be exposed to the outside of the quantum dot QD.

The quantum dot composite QD-C included in the quantum dot composition QCP according to an embodiment of the disclosure may include the additive ADa including the second functional group FG2 which is bonded to the surface of the quantum dot QD, and the first functional group FG1 connected with the second functional group FG2 and exposed to the outside of the quantum dot QD. Accordingly, the additive ADa of an embodiment may prevent the oxidation and/or corrosion of the quantum dot QD, while improving the dispersibility and charge transport properties of the quantum dots QD in the quantum dot composition, and thus, if applied to a display apparatus DD, excellent emission efficiency and life-characteristics may be shown.

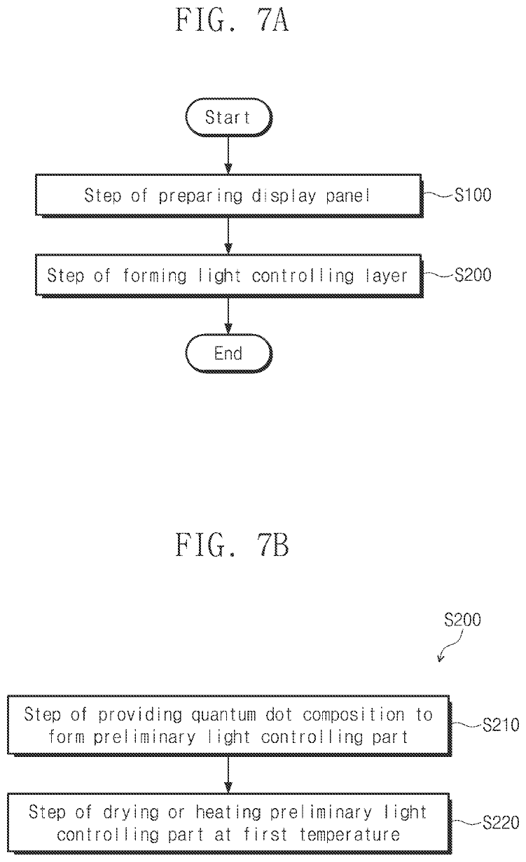

FIG. 7A is a schematic flowchart showing a manufacturing method of a display apparatus according to an embodiment. FIG. 7B is a schematic flowchart subdividing a forming step of a light controlling layer according to an embodiment (S200).

Referring to FIG. 7A, the manufacturing method of the display apparatus according to an embodiment may include a step of preparing a display panel (S100) and a step of forming a light controlling layer (S200).

Referring to FIG. 7B, the step of forming the light controlling layer according to an embodiment (S200) may include a step of providing a quantum dot composition to form a preliminary light controlling part (S210) and a step of drying or heating the preliminary light controlling part at a first temperature (S220).

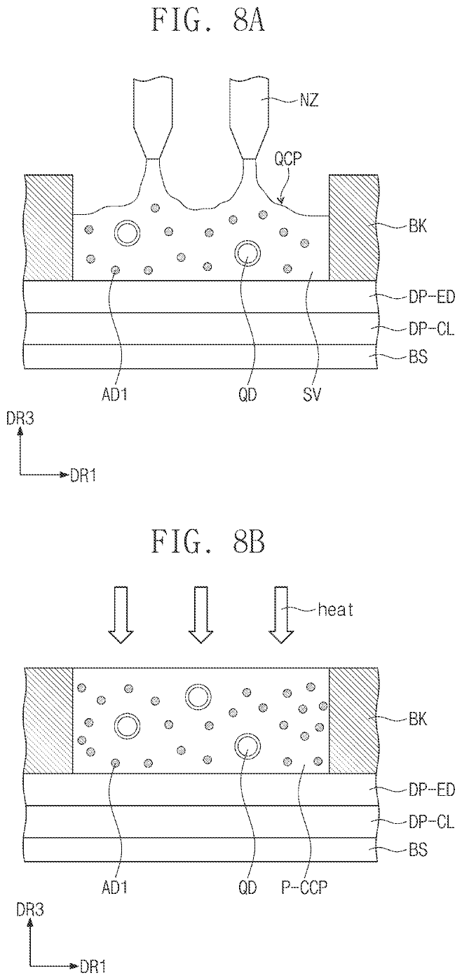

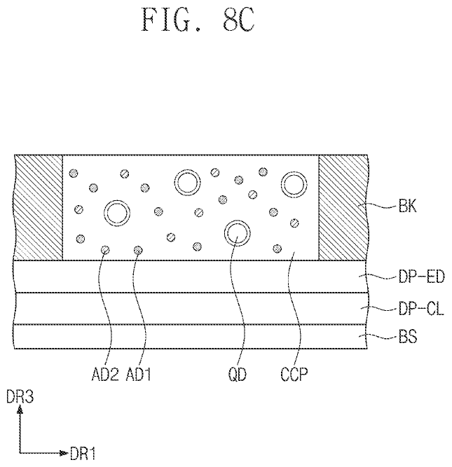

FIG. 8A to FIG. 8C are schematic cross-sectional views showing some steps among the manufacturing method of a display apparatus according to an embodiment of the disclosure. In FIG. 8A to FIG. 8C, the step of forming the light controlling layer (S200) in the manufacturing method of the display apparatus according to an embodiment of the disclosure, is shown sequentially. Hereinafter, in the explanation of the manufacturing method of the display apparatus according to an embodiment referring to FIG. 8A to FIG. 8C, a same reference symbols of a same elements as the elements explained above are given, and detailed description thereof will be omitted.

The manufacturing method of the display apparatus according to an embodiment of the disclosure may include a step of preparing a display panel and a step of forming a light controlling layer on the display panel.

Referring to FIG. 8A, the step of forming the light controlling layer during the manufacturing method of the display apparatus according to an embodiment may include a step of providing a quantum dot composition QCP on a reference plane to form a light controlling part CCP. The method of providing the quantum dot composition QCP on the reference plane is not specifically limited, but may use a spin coating method, a cast method, a Langmuir-Blodgett (LB) method, an ink jet printing method, a laser printing method, a laser induced thermal imaging (LITI) method, or the like. In FIG. 8A, the quantum dot composition QCP is applied on the reference plane through nozzles NZ, but an embodiment of the disclosure is not limited thereto, and the quantum dot composition QCP may be applied on the reference plane through various methods.

In FIG. 8A to FIG. 8C, an element providing the reference plane for applying the quantum dot composition QCP is a display device layer DP-ED as an embodiment, but an embodiment of the disclosure is not limited thereto, and the quantum dot composition QCP may be applied on a reference plane provided by a functional layer included in a light controlling member CCM, for example, a base layer BL, a color filter layer CFL, or the like. Prior to applying the quantum dot composition QCP, a step of patterning multiple partitions BK on the reference plane may be further included. For example, as in FIG. 8A, if the element providing the reference plane is the display device layer DP-ED, a step of patterning multiple partitions BK on the reference plane may be further included prior to applying the quantum dot composition QCP.

The quantum dot composition QCP may be dropped between multiple partitions BK. The quantum dot composition QCP may include a quantum dot QD and a first compound AD1, and the quantum dot composition QCP may be dropped between multiple partitions BK through nozzles NZ. The first compound AD1 may include a first functional group, and the first functional group may include at least one among an acetal group and a ketal group. The quantum dot composition QCP may form a preliminary light controlling part P-CCP. The preliminary light controlling part P-CCP formed through the quantum dot composition QCP may include the quantum dot QD and the first compound AD1. The quantum dot composition QCP may include a solvent SV. The quantum dot composition QCP may include the quantum dots QD and the first compound AD1 dispersed in the solvent SV.

Though not shown, after the step of forming the preliminary light controlling part P-CCP, at least one process among an exposing process and a pre-bake (PRB) process may be performed. For example, after forming the preliminary light controlling part P-CCP, a pre-bake process may be performed after an exposing process. The exposing process may be a step of irradiating ultraviolet light UV to the preliminary light controlling part P-CCP. The exposing process may be a step of curing by ultraviolet light of the quantum dot composition included in the preliminary light controlling part P-CCP. Particular conditions on temperature, time, etc. of the pre-bake process may be suitably selected according to the type and volume of a material. However, an embodiment of the inventive concept is not limited thereto, and the exposing process and the pre-bake process may be omitted according to circumstances.

FIG. 8B is a diagram schematically showing the step of drying or heating the preliminary light controlling part P-CCP at the first temperature (S220) in the manufacturing method of the display apparatus according to an embodiment. The step of drying or heating the preliminary light controlling part P-CCP according to an embodiment at the first temperature may be a step of drying the preliminary light controlling part P-CCP at first temperature conditions or applying heat of a first temperature to induce the hydrolysis reaction of the first compound AD1 included in the preliminary light controlling part P-CCP. In the step of forming the light controlling layer CCL according to an embodiment of the disclosure (S200), a degree of the hydrolysis of the first compound AD1 may be controlled in the step of drying or heating the preliminary light controlling part P-CCP at the first temperature (S220). Meanwhile, in the description, the step of drying or heating at the first temperature may be referred to as a “post-bake (POB) process”.

The hydrolysis reaction of the first compound AD1 may be reversible reaction. The first compound AD1 including an acetal group or a ketal group may be hydrolyzed to form a second compound AD2 including a ketone group or an aldehyde group, and an alcohol as a by-product. Since the hydrolysis reaction of the first compound AD1 is reversible reaction, the reaction may be induced in a forward direction by controlling reaction conditions such as the temperature of the reactants and the concentration of a reaction product. For example, after the hydrolysis reaction, the alcohol by-product may be removed from a reaction system. In an embodiment, the alcohol may be removed by drying at the first temperature or heating under the first temperature conditions. In conclusion, by continuously removing the alcohol produced from the reaction system, the reversible reaction of the hydrolysis reaction of the first compound AD1 may be moved to a forward direction, and thus, the moisture capturing of the first compound AD1 may become easier.

The alcohol by-product produced by the hydrolysis reaction of the first compound AD1 may be removed in the step of drying or heating the preliminary light controlling part P-CCP at the first temperature (S220). However, an embodiment of the disclosure is not limited thereto, and a portion of the alcohol produced by the hydrolysis reaction of the first compound AD1 may remain in the light controlling part CCP.

In an embodiment, the first temperature is not specifically limited, but may be less than the boiling point of the first compound AD1. For example, the first temperature may be about 0° C. to about 180° C. If the first temperature is less than the boiling point of the first compound AD1, the first compound AD1 may not be vaporized and remain at the step of drying or heating at the first temperature, and the moisture capturing may be performed more effectively.

Hereinafter, the action mechanism of the first compound AD1 included in the quantum dot composition QCP of the disclosure will be explained in detail. The first compound AD1 included in the quantum dot composition QCP according to an embodiment may be hydrolyzed according to the mechanism of Reaction 1 below. Reaction 1 below shows the hydrolysis mechanism of an acetal compound represented by Formula 1 in the first compound AD1 according to an embodiment of the disclosure. This is illustrated merely for explaining the disclosure, and an embodiment of the disclosure is not limited thereto.

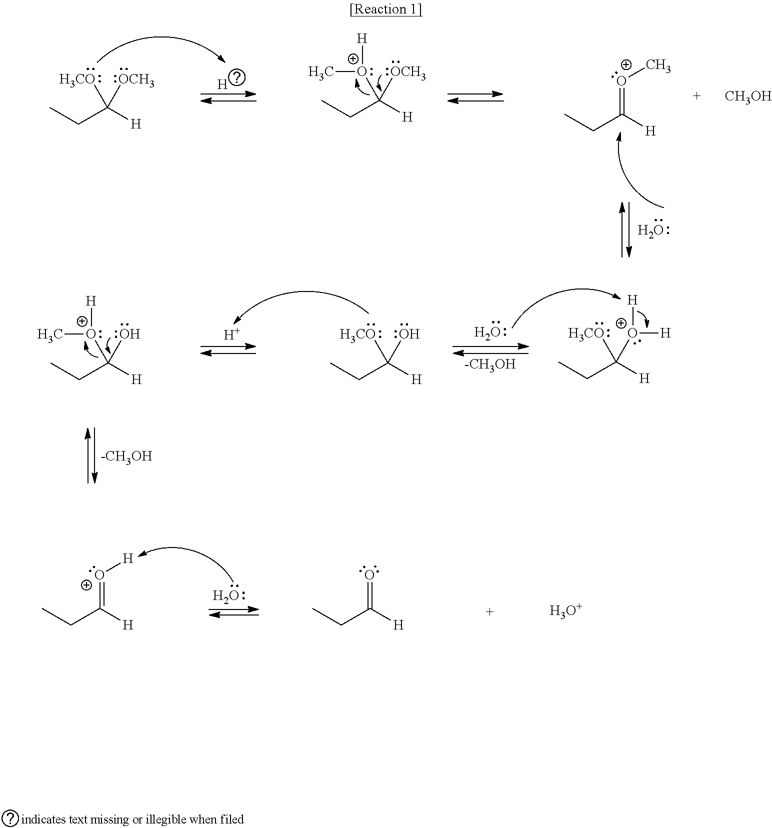

Referring to Reaction 1, the first compound AD1 including an acetal group may be hydrolyzed in the presence of moisture and may provide a second compound AD2 including an aldehyde group. In Reaction 1 above, the hydrolysis of the first compound AD1 in the presence of an acid catalyst is shown, but an embodiment of the disclosure is not limited thereto. The hydrolysis reaction of the first compound AD1 may be performed without an acid catalyst according to reaction conditions, reactants, or the like. The first compound AD1 may be deacetalized by the hydrolysis reaction. If the first compound AD1 is hydrolysed in the presence of an acid catalyst, the acid catalyst used for the hydrolysis may be any one without specific limitation if acids used in common reaction and may be suitably selected according to the molecular structure of the first compound AD1 or reaction conditions.

In an embodiment, the boiling point of the first compound AD1 may be about 180° C. or higher. If the boiling point of the first compound AD1 satisfies the above-described range, the first compound AD1 may not be removed in a process performed at a high temperature, for example, a baking process, during the manufacturing process of the display apparatus DD and may remain in the light controlling part CCP finally obtained. Accordingly, the moisture capturing by the first compound AD1 may be possible during operation, and deterioration phenomenon by the photocorrosion of the quantum dots QD may be prevented, thereby further improving the emission properties and reliability of the display apparatus DD.

Referring to FIG. 8C, the light controlling part CCP may include a quantum dot QD, a first compound AD1, and a second compound AD2. The second compound AD2 may be a material formed by the hydrolysis of the first compound AD1 included in the preliminary light controlling part P-CCP. The second compound AD2 may include a group formed by the hydrolysis of the first functional group of the first compound AD1. For example, the second compound AD2 may have a same structure as that of the first compound AD1 except for including not the first functional group of the first compound AD1 but a group formed by the hydrolysis of the first functional group. The first compound AD1 and the second compound AD2 may be included in the light controlling part CCP finally formed and present. However, an embodiment of the disclosure is not limited thereto, and the second compound AD2 may be removed in a manufacturing process of the display apparatus DD. For example, the second compound AD2 may be removed after the step of drying or heating a preliminary light controlling part P-CCP at a first temperature (S220). A same explanation on the quantum dot QD, first compound AD1, and second compound AD2 referring to FIG. 4A to FIG. 6B may be applied.

Hereinafter, the display apparatus including a light controlling part formed from the quantum dot composition according to an embodiment of the inventive concept will be explained in particular referring to an embodiment and a comparative embodiment. However, the embodiments below are illustrations for assisting the understanding of the inventive concept, and the scope of the inventive concept is not limited thereto.

### EMBODIMENTS

### 1. Preparation of Quantum Dot Composition

### 1) Example

To a propylene glycol monomethyl ether acetate (PGMEA) solution in which about 30 wt % of QD are dispersed, hexane was added, and centrifugal separation was performed to separate QD. A small amount of a solvent was added to the QD separated for dissolution, an acrylate-based monomer was mixed therewith, and the solvent was removed. About 5 wt % of a first compound was added thereto based on the total solution. Then, a scattering agent, an initiator, and a dispersing agent were added and stirred for about 30 minutes or more to obtain a quantum dot composition.

### 2) Comparative Example

A quantum dot composition was prepared by the same method as the Example except for not using the first compound in the Example. That is, the quantum dot composition of the Comparative Example corresponds to a quantum dot composition not including the first compound when compared to that of the Example.

### 2. Evaluation of Power Conversion Pattern

(Initial Process)

The quantum dot composition prepared in the Example or the Comparative Example was spin coated for about 5 seconds at about 150 rpm on a glass substrate to obtain a film. The film thus obtained was pre-baked at about 100° C. for about 100 seconds. The initial power conversion efficiency of the pre-baked film was measured.

(Process A)

The pre-baked film was exposed to ultraviolet light using a stepper and post-baked at about 180° C. for about 30 minutes. The first power conversion efficiency of the exposed and post-baked film was measured.

(Process B)

On the post-baked film, a capping layer including SiNₓ was formed to a thickness of about 300 nm by sputtering to form a power conversion pattern. The second power conversion efficiency of the power conversion pattern thus formed was measured.

(1) Evaluation of Power Conversion Efficiency

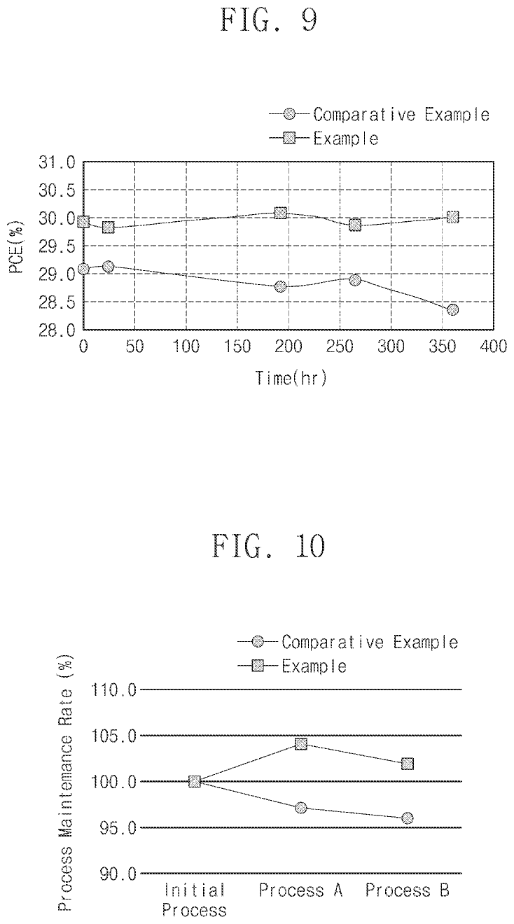

FIG. 9 is a diagram showing power conversion efficiency change in accordance with time of the Example and the Comparative Example. The power conversion efficiency of the Example and Comparative Example in FIG. 9 was measured by QE-2000 (Otsuka Co.) apparatus, and measured by setting a first reference by putting a bare glass on a blue BLU (about 455 nm) covered with a diffusing film and measuring using a detector, and then, calculating a light-emitting peak area of converted light against a blue light absorption peak area. For example, the power conversion efficiency (PCE) of the Example and Comparative Example could be calculated by Equation 1 below.

PCE=(A₂/A₁)×100 [Equation 1]

In Equation 1, A₁ means the area of a blue light absorption spectrum, and A₂ means the area of a light-emitting spectrum for converted light. For example, A₁ may correspond to an absorption peak area for blue light absorbed by quantum dots. A₂ may correspond to a light-emitting peak area for light converted by quantum dots.

Referring to FIG. 9, it could be confirmed that the power conversion efficiencies of the Example and Comparative Example are similar as about 30% and about 20%, respectively, at the initiation time of driving, and the power conversion efficiency of the display apparatus according to the Example, using the quantum dot composition of an embodiment, is maintained similarly even after about 350 hours. In comparison, it could be found that the power conversion efficiency of the display apparatus of the Comparative Example using the quantum dot composition of the Comparative Example is decreased gradually to about 250 hours and then, decreased rapidly after about 250 hours. Accordingly, it could be confirmed that the display apparatus of an embodiment, using the quantum dot composition of an embodiment could maintain emission efficiency excellent despite the passage of time.

### (2) Evaluation of Process Maintenance Rate

FIG. 10 is a graph showing after measuring the process maintenance rates of the display apparatuses according to the Example and Comparative Example. Meanwhile, in the description, the process maintenance rate means the ratio of the power conversion efficiency after performing a process with respect to the power conversion efficiency before performing a process. In FIG. 10, the process maintenance rate of each process of the display apparatuses according to the Example and the Comparative Example was evaluated to confirm the deterioration prevention effects of quantum dots by the first compound included in the quantum dot composition of an embodiment, and the results are shown. In FIG. 10, a first process maintenance rate (PMR1) in “Process A” could be calculated according to Equation 2 below, and a second process maintenance rate (PMR2) in “Process B” could be calculated according to Equation 3 below.

PMR1=(E_{A}/E_{R})×100 [Equation 2]

PMR1=(E_{B}/E_{R})×100 [Equation 3]

In Equation 2 and Equation 3, E_{R} means power conversion efficiency measured after an “initial process”, E_{A} means power conversion efficiency measured after “Process A”, and E_{B} means power conversion efficiency measured after “Process B”.

Referring to FIG. 10, it could be confirmed that the process maintenance rates in the preparation of the Example using the quantum dot composition of an embodiment are shown about 104% and about 102% after Process A and Process B, respectively. That is, in the display apparatus of an embodiment, it could be confirmed that the power conversion efficiency after Process A and the power conversion efficiency after Process B were improved further than the power conversion efficiency after the initial process. In comparison, the process maintenance rates in the preparation of the Comparative Example using the quantum dot composition of the Comparative Example were about 97% and about 96% after Process A and Process B, respectively, and it could be confirmed that the process maintenance rate was reduced according to the progress of the process. Accordingly, it could be found that the display apparatus of an embodiment may show improved reliability, because the quantum dot composition including the first compound is used, and humidity present around the quantum dots could be effectively removed during driving.

A display apparatus DD including a light controlling part CCP formed from a quantum dot composition QCP of an embodiment may show improved emission properties and reliability. The emission properties of the quantum dots QD may be reduced due to the deterioration by external environments, for example, moisture, heat, light, or the like. According to the disclosure, a first compound AD1 including a first functional group which may capture moisture is included in the quantum dot composition QCP. Accordingly, the quantum dots QD could be effectively protected from moisture penetrated during processing, and moisture present around the quantum dots QD may be removed even during operation. Accordingly, the deterioration due to the photocorrosion may be prevented, and the display apparatus DD showing improved emission properties and reliability may be accomplished.

According to an embodiment of the disclosure, by a quantum dot QD and a first compound AD1 including at least one among an acetal group and a ketal group, included in at least one among multiple light controlling parts CCP, the oxidation and/or corrosion of the quantum dot QD may be prevented, and the emission efficiency and reliability of a display apparatus DD may be improved.

According to an embodiment of the disclosure, in a process of forming at least one among multiple light controlling parts CCP, quantum dots QD may be protected from moisture, reliability may be improved, and the oxidation and/or corrosion of the quantum dots QD may be prevented during operation, and accordingly, a manufacturing method of a display apparatus showing excellent emission efficiency and improved life-characteristics may be provided.

The above description is an example of technical features of the disclosure, and those skilled in the art to which the disclosure pertains will be able to make various modifications and variations. Therefore, the embodiments of the disclosure described above may be implemented separately or in combination with each other.

Although the embodiments of the disclosure have been described, it is understood that the disclosure should not be limited to these embodiments, but various changes and modifications can be made by one ordinary skilled in the art within the spirit and scope of the disclosure as hereinafter claimed.

What is claimed is:

1. A quantum dot composition comprising:
a quantum dot;
a compound comprising a first functional group; and
a solvent,
wherein the first functional group comprises at least one among an acetal group and a ketal group.

2. The quantum dot composition of claim 1, wherein an amount of the compound is about 30 wt % or less based on about 100 wt % of a total amount of the quantum dot composition.

3. The quantum dot composition of claim 1, wherein the compound is represented by the following Formula 1: 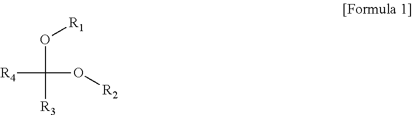
in Formula 1,
R₁ and R₂ are each independently a substituted or unsubstituted alkyl group of 1 to 20 carbon atoms, or R₁ and R₂ are combined with each other to form a ring, and
R₃ and R₄ are each independently a hydrogen atom, a deuterium atom, a halogen atom, a substituted or unsubstituted alkyl group of 1 to 20 carbon atoms, a substituted or unsubstituted alkenyl group of 2 to 20 carbon atoms, a substituted or unsubstituted alkynyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms.

4. The quantum dot composition of claim 3, wherein the compound is represented by any one among the following Formula 1-1 to Formula 1-3: 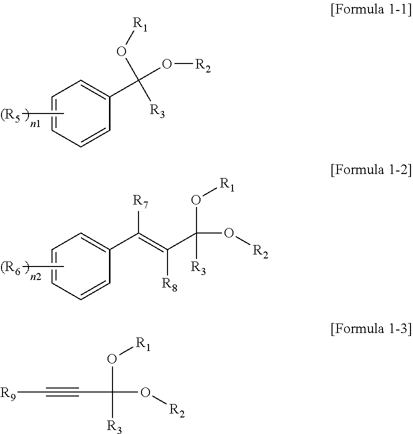
in Formula 1-1 to Formula 1-3,
R₅ and R₆ are each independently a hydrogen atom, a deuterium atom, a halogen atom, a substituted or unsubstituted carboxyl group, a substituted or unsubstituted thio group, a substituted or unsubstituted amine group, a substituted or unsubstituted phosphine group, a substituted or unsubstituted hydroxyl group, a substituted or unsubstituted oxy group, a substituted or unsubstituted nitro group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring,
R₇ to R₉ are each independently a hydrogen atom, a deuterium atom, a halogen atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
n1 and n2 are each independently an integer of 0 to 5, and
R₁ to R₃ are the same as defined in Formula 1 above.

5. The quantum dot composition of claim 1, wherein the compound further comprises a second functional group which is bonded to a surface of the quantum dot and is different from the first functional group.

6. The quantum dot composition of claim 5, wherein the second functional group comprises at least one among a carboxyl group, a thio group, an amine group, a phosphine group, and a hydroxyl group.

7. The quantum dot composition of claim 1, wherein the compound is represented by any one among the following Formula 2-1 to Formula 2-5: 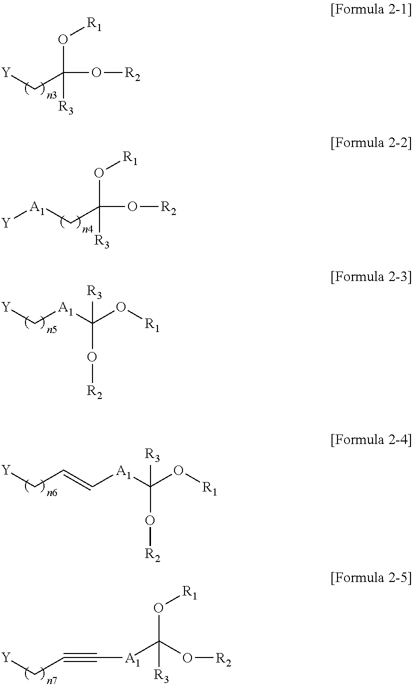
in Formula 2-1 to Formula 2-5,
R₁ and R₂ are each independently a substituted or unsubstituted alkyl group of 1 to 20 carbon atoms, or R₁ and R₂ are combined with each other to form a ring,
R₃ is a hydrogen atom, a deuterium atom, a halogen atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
Y is a substituted or unsubstituted carboxyl group, a substituted or unsubstituted thio group, a substituted or unsubstituted amine group, a substituted or unsubstituted phosphine group, or a substituted or unsubstituted hydroxyl group,
A₁ is a substituted or unsubstituted arylene group of 6 to 30 ring-forming carbon atoms, or a substituted or unsubstituted heteroarylene group of 2 to 30 ring-forming carbon atoms, and
n3 to n7 are each independently an integer of 0 to 20.

8. The quantum dot composition of claim 1, wherein
the compound further comprises a third functional group which is different from the first functional group, and
the third functional group comprises a (meth)acrylate group.

9. The quantum dot composition of claim 1, wherein a boiling point of the compound is about 180° C. or higher.

10. The quantum dot composition of claim 1, wherein the quantum dot comprises a core and a shell wrapping the core.

11. A display apparatus, comprising:
a light emitting device outputting source light; and
a light controlling layer disposed on the light emitting device and comprising multiple light controlling parts, wherein
at least one among the multiple light controlling parts comprises:
a quantum dot; and
an additive,
the additive comprises:
a first functional group; or
a group formed by a hydrolysis of the first functional group, and
the first functional group comprises at least one among an acetal group and a ketal group.

12. The display apparatus of claim 11, wherein the additive is represented by the following Formula 1 or Formula 1A: 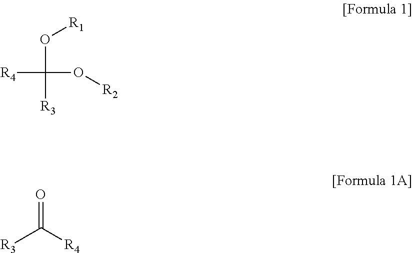
in Formula 1 and Formula 1A,
R₁ and R₂ are each independently a substituted or unsubstituted alkyl group of 1 to 20 carbon atoms, or R₁ and R₂ are combined with each other to form a ring, and
R₃ and R₄ are each independently a hydrogen atom, a deuterium atom, a halogen atom, a substituted or unsubstituted alkyl group of 1 to 20 carbon atoms, a substituted or unsubstituted alkenyl group of 2 to 20 carbon atoms, a substituted or unsubstituted alkynyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms.

13. The display apparatus of claim 11, wherein the additive is represented by any one among the following Formula 1-1 to Formula 1-6: 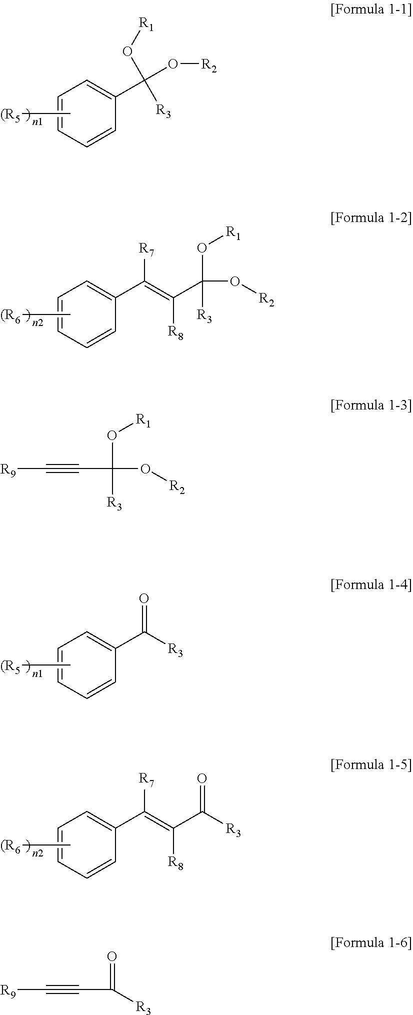
in Formula 1-1 to Formula 1-6,
R₁ and R₂ are each independently a substituted or unsubstituted alkyl group of 1 to 20 carbon atoms, or R₁ and R₂ are combined with each other to form a ring,
R₃ and R₄ are each independently a hydrogen atom, a deuterium atom, a halogen atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
R₅ and R₆ are each independently a hydrogen atom, a deuterium atom, a halogen atom, a substituted or unsubstituted carboxyl group, a substituted or unsubstituted thio group, a substituted or unsubstituted amine group, a substituted or unsubstituted phosphine group, a substituted or unsubstituted hydroxyl group, a substituted or unsubstituted oxy group, a substituted or unsubstituted nitro group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring,
R₇ to R₉ are each independently a hydrogen atom, a deuterium atom, a halogen atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, and
n1 and n2 are each independently an integer of 0 to 5.

14. The display apparatus of claim 11, wherein
the additive further comprises a second functional group which is bonded to a surface of the quantum dot and is different from the first functional group, and
the second functional group comprises at least one among a carboxyl group, a thio group, an amine group, a phosphine group, and a hydroxyl group.

15. The display apparatus of claim 11, wherein the additive is represented by any one among the following Formula 2-1 to Formula 2-10: 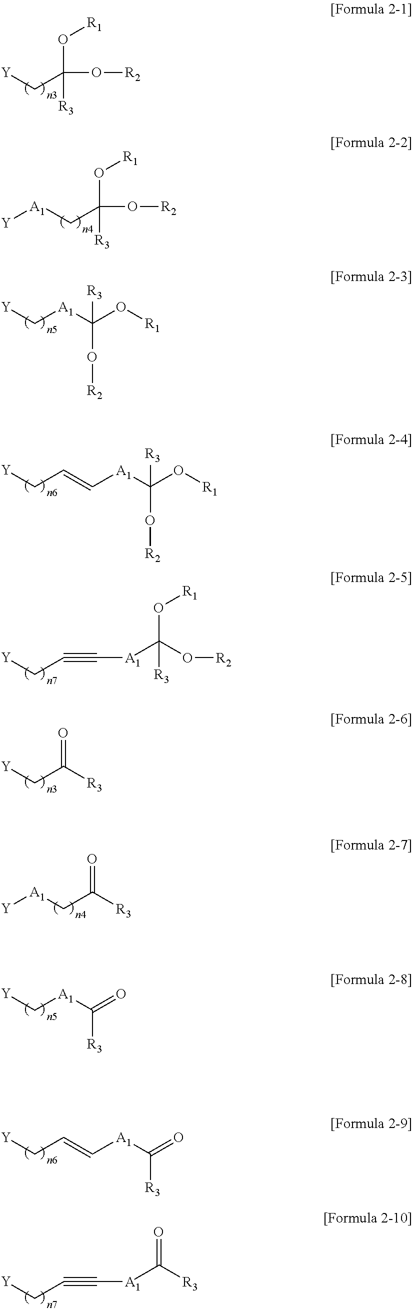
in Formula 2-1 to Formula 2-10,
R₁ and R₂ are each independently a substituted or unsubstituted alkyl group of 1 to 20 carbon atoms, or R₁ and R₂ are combined with each other to form a ring,
R₃ is a hydrogen atom, a deuterium atom, a halogen atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
Y is a substituted or unsubstituted carboxyl group, a substituted or unsubstituted thio group, a substituted or unsubstituted amine group, a substituted or unsubstituted phosphine group, or a substituted or unsubstituted hydroxyl group,
A₁ is a substituted or unsubstituted arylene group of 6 to 30 ring-forming carbon atoms, or a substituted or unsubstituted heteroarylene group of 2 to 30 ring-forming carbon atoms, and
n3 to n7 are each independently an integer of 0 to 20.

16. The display apparatus of claim 11, wherein
the additive further comprises a third functional group which is different from the first functional group, and
the third functional group comprises a (meth)acrylate group.

17. The display apparatus of claim 11, wherein
the source light is light of a first wavelength, and
the light controlling layer comprises:
a first light controlling part converting the source light into light of a second wavelength which is different from the first wavelength;
a second light controlling part converting the source light into light of a third wavelength which is different from the first wavelength and the second wavelength; and
a third light controlling part transmitting the source light.

18. A manufacturing method of a display apparatus, the method comprising:
preparing a display panel; and
forming a light controlling layer comprising multiple light controlling parts on the display panel, wherein
the forming of the light controlling layer comprising the multiple light controlling parts on the display panel comprises forming at least one light controlling part among the multiple light controlling parts on the display panel,
the forming of at least one light controlling part among the multiple light controlling parts on the display panel, comprises:
providing a quantum dot composition comprising a quantum dot and a compound comprising a functional group to form a preliminary light controlling part; and
drying or heating the preliminary light controlling part at a temperature, and
the functional group comprises at least one among an acetal group and a ketal group.

19. The manufacturing method of a display apparatus of claim 18, wherein an amount of the compound is about 30 wt % or less based on about 100 wt % of a total amount of the quantum dot composition.

20. The manufacturing method of a display apparatus of claim 18, wherein the temperature is lower than a boiling point of the compound.
